(19) United States
(12) Patent Application Publication
(10) Pub. No.: US 2025/0327704 A1
(43) Pub. Date: Oct. 23, 2025

(54) ELECTROMAGNETIC WAVE DETECTOR AND ELECTROMAGNETIC WAVE DETECTOR ARRAY

(71) Applicant: Mitsubishi Electric Corporation, Tokyo (JP)

(72) Inventors: Masaaki SHIMATANI, Chiyoda-ku, Tokyo (JP); Shimpei OGAWA, Chiyoda-ku, Tokyo (JP); Manabu IWAKAWA, Chiyoda-ku, Tokyo (JP); Shoichiro FUKUSHIMA, Chiyoda-ku, Tokyo (JP)

(73) Assignee: Mitsubishi Electric Corporation, Tokyo (JP)

(21) Appl. No.: 18/855,662

(22) PCT Filed: Jan. 26, 2023
(86) PCT No.: PCT/JP2023/002515

§ 371 Date: Oct. 10, 2024

(30) Foreign Application Priority Data
Apr. 22, 2022 (JP) 2022-070748

(51) Int. Cl. G01J 1/04; G01J 1/44

(52) U.S. Cl. CPC G01J 1/0422; G01J 1/047; G01J 1/44; G01J 2001/446

(57) ABSTRACT

An electromagnetic wave detector includes a heat-absorbing layer, an insulating film, a two-dimensional material layer, and a first electrode portion. The heat-absorbing layer includes a thermoelectric material layer and a phase-transition material layer. The insulating film is disposed on part of the heat-absorbing layer. The two-dimensional material layer is disposed on the heat-absorbing layer and the insulating film and is electrically connected to the heat-absorbing layer. The first electrode portion is disposed on the insulating film and is electrically connected to the heat-absorbing layer with the two-dimensional material layer in between.

### TECHNICAL FIELD

The present disclosure relates to an electromagnetic wave detector and an electromagnetic wave detector array.

### BACKGROUND ART

A graphene, which is an example of the two-dimensional material layer, is known as a material of an electromagnetic wave detection layer used for a next-generation electromagnetic wave detector. The graphene is extremely high in mobility. The graphene has an absorptivity as low as 2.3%. Thus, a sensitivity enhancement technique for an electromagnetic wave detector including the graphene as the two-dimensional material layer has been proposed.

For example, U.S. Patent Application Publication No. 2015/0243826 (PTL 1) proposes a detector having the following structure. Specifically, in U.S. Patent Application Publication No. 2015/0243826, two or more dielectric layers are provided on an n-type semiconductor layer. A graphene layer is formed on two dielectric layers and on a surface portion of the n-type semiconductor layer located between the two dielectric layers. Source and drain electrodes connected to the opposite ends of the graphene layer are disposed on the dielectric layer. A gate electrode is connected to the n-type semiconductor layer.

In the detector described above, a voltage is applied to the graphene layer serving as a channel via the source and drain electrodes. This amplifies photocarriers generated in the n-type semiconductor layer, leading to improved sensitivity of the detector. When a voltage is applied to the gate electrode and the source electrode or the drain electrode, Schottky connection between the graphene and the n-type semiconductor layer enables OFF operation.

### CITATION LIST

### Patent Literature

PTL 1: U.S. Patent Application Publication No. 2015/0243826

### SUMMARY OF INVENTION

### Technical Problem

In the detector (electromagnetic wave detector) described in the above publication, an electromagnetic wave is detected by the photocarriers generated by irradiation of the semiconductor layer with the electromagnetic wave. Thus, the sensitivity of the detector depends on the quantum efficiency of the semiconductor layer. The quantum efficiency of the semiconductor layer may not be sufficiently high depending on wavelengths of magnetic waves. This results in insufficient detection sensitivity of the electromagnetic wave detector.

The present disclosure has been made in view of the above problem. An object of the present disclosure is to provide an electromagnetic wave detector and an electromagnetic wave detector array that can have improved sensitivity.

### Solution to Problem

An electromagnetic wave detector according to the present disclosure includes a heat-absorbing layer, an insulating film, a two-dimensional material layer, and a first electrode portion. The heat-absorbing layer includes a thermoelectric material layer and a phase-transition material layer. The insulating film is disposed on part of the heat-absorbing layer. The two-dimensional material layer is disposed on the heat-absorbing layer and the insulating film and is electrically connected to the heat-absorbing layer. The first electrode portion is disposed on the insulating film and is electrically connected to the heat-absorbing layer with the two-dimensional material layer in between.

### Advantageous Effects of Invention

The electromagnetic wave detector according to the present disclosure can have improved sensitivity due to the heat-absorbing layer.

### BRIEF DESCRIPTION OF DRAWINGS

FIG. 1 is a sectional view schematically showing a configuration of an electromagnetic wave detector according to Embodiment 1.

FIG. 2 is a top view schematically showing the configuration of the electromagnetic wave detector according to Embodiment 1.

FIG. 3 is a sectional view schematically showing a configuration of an electromagnetic wave detector according to a first modification of Embodiment 1.

FIG. 4 is a sectional view schematically showing a configuration of an electromagnetic wave detector according to a second modification of Embodiment 1.

FIG. 5 is a sectional view schematically showing a configuration of an electromagnetic wave detector according to a third modification of Embodiment 1.

FIG. 6 is a sectional view schematically showing a configuration of an electromagnetic wave detector according to Embodiment 2.

FIG. 7 is a sectional view schematically showing a configuration of an electromagnetic wave detector according to Embodiment 3.

FIG. 8 is a sectional view schematically showing a configuration of an electromagnetic wave detector according to a first modification of Embodiment 3.

FIG. 9 is a sectional view schematically showing a configuration of an electromagnetic wave detector according to Embodiment 4.

FIG. 10 is a sectional view schematically showing a configuration of an electromagnetic wave detector according to a first modification of Embodiment 4.

FIG. 11 is a sectional view schematically showing a configuration of an electromagnetic wave detector according to a second modification of Embodiment 4.

FIG. 12 is a top view schematically showing the configuration of the electromagnetic wave detector according to the second modification of Embodiment 4.

FIG. 13 is a top view schematically showing a configuration of an electromagnetic wave detector according to a third modification of Embodiment 4.

FIG. 14 is a sectional view schematically showing a configuration of an electromagnetic wave detector according to Embodiment 5.

FIG. 15 is a sectional view schematically showing a configuration of an electromagnetic wave detector according to Embodiment 6.

FIG. 16 is a sectional view schematically showing a configuration of an electromagnetic wave detector according to a first modification of Embodiment 6.

FIG. 17 is a sectional view schematically showing a configuration of an electromagnetic wave detector according to Embodiment 7.

FIG. 18 is a sectional view schematically showing a configuration of an electromagnetic wave detector according to a first modification of Embodiment 7.

FIG. 19 is a sectional view schematically showing a configuration of an electromagnetic wave detector according to Embodiment 8.

FIG. 20 is a sectional view schematically showing a configuration of an electromagnetic wave detector according to Embodiment 9.

FIG. 21 is a sectional view schematically showing a configuration of an electromagnetic wave detector according to a first modification of Embodiment 9.

FIG. 22 is a sectional view schematically showing a configuration of an electromagnetic wave detector according to a second modification of Embodiment 9.

FIG. 23 is a sectional view schematically showing a configuration of an electromagnetic wave detector according to a third modification of Embodiment 9.

FIG. 24 is a sectional view schematically showing a configuration of an electromagnetic wave detector according to Embodiment 10.

FIG. 25 is a sectional view schematically showing a configuration of an electromagnetic wave detector according to a first modification of Embodiment 10.

FIG. 26 is a sectional view schematically showing a configuration of an electromagnetic wave detector according to a second modification of Embodiment 10.

FIG. 27 is a top view schematically showing the configuration of the electromagnetic wave detector according to the second modification of Embodiment 10.

FIG. 28 is a top view schematically showing a configuration of an electromagnetic wave detector array according to Embodiment 11.

FIG. 29 is a sectional view schematically showing a configuration of an electromagnetic wave detector according to a first modification of Embodiment 11.

FIG. 30 is a sectional view schematically showing a configuration of an electromagnetic wave detector according to Embodiment 12.

FIG. 31 is a sectional view schematically showing a configuration of an electromagnetic wave detector according to Embodiment 13.

### DESCRIPTION OF EMBODIMENTS

Embodiments will be described below with reference to the drawings. In the following description, the same or corresponding components are denoted by the same reference characters, and redundant description will not be repeated.

In the embodiments described below, each figure is schematic and conceptually illustrates a function or a structure. Further, the present disclosure is not limited by the embodiments described below. A basic configuration of an electromagnetic wave detector is the same among all the embodiments unless stated specifically. Further, the same or corresponding components are denoted by the same reference characters as described above. This applies entirely to the specification.

Although each of the embodiments will describe below a configuration of the electromagnetic wave detector when detecting visible light or infrared light, the light detected by the clectromagnetic wave detector of the present disclosure is not limited to the visible light or the infrared light. Each of the embodiments described below is also effective as a detector that detects electric waves such as X-rays, ultraviolet light, near-infrared light, terahertz (THz) waves, and microwaved in addition to the visible light and the infrared light. It should be noted that the light and electric waves will be collectively referred to as “electromagnetic wave” in the embodiments of the present disclosure.

Further, in the present embodiment, the terms “p-type graphene” and “n-type graphene” may be used as a graphene. In the embodiments described below, the p-type graphene refers to a graphene having a larger number of holes than those of a graphene in an intrinsic state, and the n-type graphene refers to a graphene having a larger number of electrons than those of the graphene in the intrinsic state. In other words, an n type material is a material having electron donating properties. In contrast, a p type material is a material having electron attracting properties.

Further, a material in which electrons are dominant when imbalance in charges is observed throughout a molecule may be referred to as n type. A material in which holes are dominant when imbalance in charges is observed throughout the molecule may be referred to as p type. Any one of an organic substance and an inorganic substance or a mixture of the organic substance and the inorganic substance may be used as a material of a member in contact with the graphene, which is an example of the two-dimensional material layer.

Further, a plasmon resonance phenomenon such as a surface plasmon resonance phenomenon, which is an interaction between a metal surface and light, a phenomenon referred to as pseudo surface plasmon resonance, which means resonance for a metal surface in a range other than a visible light range and a near-infrared light range, and a phenomenon referred to as metamaterial or plasmonic metamaterial, which means manipulation of a wavelength by a structure having a size equal to or less than a wavelength, will not be particularly distinguished from one another by the names and will be handled equivalently in terms of effects exerted by the phenomena. Herein, each of these resonances will be referred to as surface plasmon resonance, plasmon resonance, or, merely, resonance.

Although the graphene is described as an example material of the two-dimensional material layer in the embodiments described below, the material of the two-dimensional material layer is not limited to the graphene. For example, as the material of the two-dimensional material layer, materials such as transition metal dichalcogenide (TMD), black phosphorus, silicene (two-dimensional honeycomb structure by silicon atoms), germanene (two-dimensional honeycomb structure by germanium atoms) can be applied. Examples of the transition metal dichalcogenide include transition metal dichalcogenides such as molybdenum disulfide (MoS₂), tungsten disulfide (WS₂), and tungsten diselenide (WSe₂).

More preferably, the two-dimensional material layer includes any material selected from the group consisting of graphene, transition metal dichalcogenide (TMD), black phosphorus, silicene (two-dimensional honeycomb structure by silicon atoms), a graphene nanoribbon, and borophene.

These materials have a structure similar to that of the graphene. In these materials, atoms are arranged in the form of a single layer in a two-dimensional plane. Therefore, also when each of these materials is applied to the two-dimensional material layer, the same functions and effects as those when the graphene is applied to the two-dimensional material layer can be achieved.

Further, what is represented by an insulating layer in the present embodiment is a layer of an insulator having such a thickness that does not cause a tunnel current.

### Embodiment 1

### <Configuration of Electromagnetic Wave Detector 100>

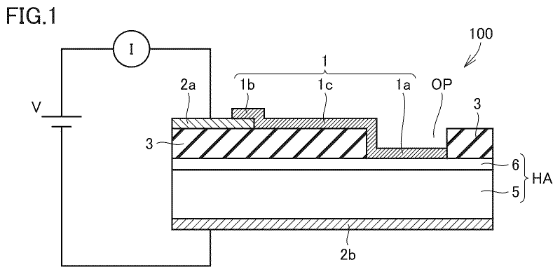

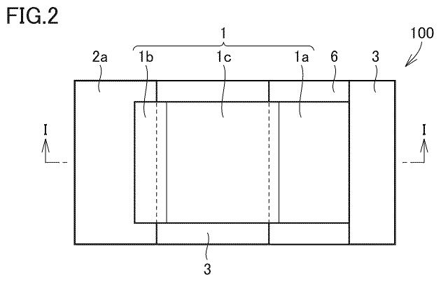

A configuration of an electromagnetic wave detector 100 according to Embodiment 1 will be described with reference to FIGS. 1 to 5. FIG. 1 is a sectional view taken along the line I-I of FIG. 2.

As shown in FIGS. 1 and 2, electromagnetic wave detector 100 includes a two-dimensional material layer 1, a first electrode portion 2a, a second electrode portion 2b, an insulating film 3, and a heat-absorbing layer HA. Heat-absorbing layer HA includes a thermoelectric material layer 5 and a phase-transition material layer 6. Two-dimensional material layer 1, first electrode portion 2a, second electrode portion 2b, thermoelectric material layer 5, and phase-transition material layer 6 are electrically connected in order of first electrode portion 2a, two-dimensional material layer 1, phase-transition material layer 6, thermoelectric material layer 5, and second electrode portion 2b. Electromagnetic wave detector 100 further includes at least any of an ammeter I or a voltmeter. Electromagnetic wave detector 100 shown in FIG. 1 further includes ammeter I.

Two-dimensional material layer 1 is electrically connected to heat-absorbing layer HA. Two-dimensional material layer 1 is electrically connected to phase-transition material layer 6. Two-dimensional material layer 1 is disposed on heat-absorbing layer HA and insulating film 3. Two-dimensional material layer 1 is disposed on first electrode portion 2a, insulating film 3, and phase-transition material layer 6. In other words, two-dimensional material layer 1 is in contact with first electrode portion 2a, insulating film 3, and phase-transition material layer 6. Two-dimensional material layer 1 includes a first portion 1a, a second portion 1b, and a third portion 1c. First portion 1a is disposed on phase-transition material layer 6. First portion 1a is electrically connected to phase-transition material layer 6. Second portion 1b is disposed on first electrode portion 2a. Second portion 1b is electrically connected to first electrode portion 2a. Third portion 1c electrically connects first portion 1a to second portion 1b. First portion 1a is connected to second portion 1b by third portion 1c. In the present embodiment, third portion 1c is disposed on insulating film 3.

First portion 1a, second portion 1b, and third portion 1c may have the same thickness. In the direction in which two-dimensional material layer 1 is overlaid on phase-transition material layer 6, the distance between the top-side surface of first portion 1a and the top-side surface of phase-transition material layer 6 is smaller than the distance between the top-side surface of second portion 1b and the top-side surface of phase-transition material layer 6. Although not shown, the surface of two-dimensional material layer 1 has unevenness resulting from first portion 1a, second portion 1b, and third portion 1c.

First electrode portion 2a is electrically connected to two-dimensional material layer 1. First electrode portion 2a is electrically connected to two-dimensional material layer 1 without phase-transition material layer 6 in between. In the present embodiment, first electrode portion 2a is directly connected to two-dimensional material layer 1. First electrode portion 2a is disposed on the bottom side of two-dimensional material layer 1. Although not shown, first electrode portion 2a may also be disposed on the top side of two-dimensional material layer 1. First electrode portion 2a is electrically connected to heat-absorbing layer HA with two-dimensional material layer 1 in between.

Second electrode portion 2b is electrically connected to two-dimensional material layer 1 with thermoelectric material layer 5 and phase-transition material layer 6 in between. Second electrode portion 2b is electrically connected to heat-absorbing layer HA. Second electrode portion 2b is in contact with thermoelectric material layer 5. In electromagnetic wave detector 100 shown in FIG. 1, second electrode portion 2b entirely covers the bottom surface of thermoelectric material layer 5. Electromagnetic wave detector 100 with the bottom surface thereof entirely covered with second electrode portion 2b is suitable for the case where an electromagnetic wave to be detected enters electromagnetic wave detector 100 only from the top side. The electromagnetic wave that has entered electromagnetic wave detector 100 from the top side passes through thermoelectric material layer 5 and phase-transition material layer 6 and is then reflected off second electrode portion 2b. The electromagnetic wave reflected off second electrode portion 2b again enters thermoelectric material layer 5 and phase-transition material layer 6 from the bottom side. Thus, the electromagnetic wave enters thermoelectric material layer 5 and phase-transition material layer 6 from each of the top side and the bottom side. This leads to improved electromagnetic wave absorption rates of thermoelectric material layer 5 and phase-transition material layer 6.

Although not shown, second electrode portion 2b may not entirely cover thermoelectric material layer 5. In other words, second electrode portion 2b is only required to be in contact with part of thermoelectric material layer 5. For example, second electrode portion 2b is only required to be in contact with part of thermoelectric material layer 5. When the bottom surface of thermoelectric material layer 5 is exposed from second electrode portion 2b, electromagnetic wave detector 100 can detect an electromagnetic wave that has entered from the bottom side.

Insulating film 3 is disposed on part of heat-absorbing layer HA. Insulating film 3 is disposed on phase-transition material layer 6. Insulating film 3 is disposed on the top side of phase-transition material layer 6. An opening OP is formed in insulating film 3. Opening OP passes through insulating film 3. Phase-transition material layer 6 is exposed from insulating film 3 at opening OP. In other words, phase-transition material layer 6 is not covered with insulating film 3 at opening OP. Part of phase-transition material layer 6 is not covered with insulating film 3 at opening OP.

Two-dimensional material layer 1 is electrically connected to phase-transition material layer 6 at opening OP. Two-dimensional material layer 1 extends from over opening OP to insulating film 3. In the present embodiment, two-dimensional material layer 1 extends from over opening OP to over insulating film 3. First portion 1a of two-dimensional material layer 1 is disposed on phase-transition material layer 6 in opening OP. Preferably, two-dimensional material layer 1 is joined to phase-transition material layer 6 by a Schottky junction at opening OP. First portion 1a of two-dimensional material layer 1 is joined to phase-transition material layer 6 at opening OP. Insulating film 3 separates second portion 1b and third portion 1c of two-dimensional material layer 1 from phase-transition material layer 6.

A first end of two-dimensional material layer 1 is disposed in opening OP. A second end of two-dimensional material layer 1 is disposed over second electrode portion 2b. The first end and the second end of two-dimensional material layer 1 are ends of two-dimensional material layer 1 in the longitudinal direction. In FIG. 1, the first end of two-dimensional material layer 1 is disposed opposite to first electrode portion 2a relative to the center of opening OP in the in-plane direction of phase-transition material layer 6, and the second end of two-dimensional material layer 1 is disposed on the first electrode portion 2a side relative to the center of opening OP. Although not shown, each of the first end and the second end of two-dimensional material layer 1 may be disposed on the first electrode portion 2a side relative to the center of opening OP.

Although not shown, two-dimensional material layer 1 may be disposed so as to expose part of the top-side surface of phase-transition material layer 6 at opening OP. As shown in FIG. 1, two-dimensional material layer 1 may be disposed so as to entirely cover the top-side surface of phase-transition material layer 6 at opening OP.

The bottom surface of insulating film 3 is in contact with the upper surface of phase-transition material layer 6. Part of the upper surface of phase-transition material layer 6 is in contact with two-dimensional material layer 1. In other words, insulating film 3 is disposed on the bottom side relative to two-dimensional material layer 1. First electrode portion 2a is disposed on insulating film 3. First electrode portion 2a is disposed at a position apart from opening OP.

Phase-transition material layer 6 is electrically connected to at least any of first electrode portion 2a, second electrode portion 2b, two-dimensional material layer 1, and thermoelectric material layer 5. In the present embodiment, phase-transition material layer 6 is electrically connected to first electrode portion 2a, second electrode portion 2b, and thermoelectric material layer 5. In FIG. 1, insulating film 3 is disposed on phase-transition material layer 6. In other words, phase-transition material layer 6 is covered with insulating film 3. Phase-transition material layer 6 is disposed on thermoelectric material layer 5. Phase-transition material layer 6 is in contact with thermoelectric material layer 5. Phase-transition material layer 6 is disposed between first electrode portion 2a and second electrode portion 2b.

Phase-transition material layer 6 has sensitivity to a wavelength (detection wavelength) of an electromagnetic wave to be detected by electromagnetic wave detector 100. Thus, when phase-transition material layer 6 is irradiated with the electromagnetic wave having the detection wavelength, resistance changes in phase-transition material layer 6. In other words, when phase-transition material layer 6 is irradiated with the electromagnetic wave having the detection wavelength, a phase transition occurs in phase-transition material layer 6.

In the present embodiment, phase-transition material layer 6 is disposed such that the resistance between first electrode portion 2a and second electrode portion 2b changes when the resistance of phase-transition material layer 6 changes by irradiation with the electromagnetic wave.

Thermoelectric material layer 5 is electrically connected to at least any of first electrode portion 2a, second electrode portion 2b, two-dimensional material layer 1, and phase-transition material layer 6. In the present embodiment, thermoelectric material layer 5 is electrically connected to first electrode portion 2a, second electrode portion 2b, and phase-transition material layer 6. In FIG. 1, second electrode portion 2b is formed below thermoelectric material layer 5, and phase-transition material layer 6 is formed on thermoelectric material layer 5. Thermoelectric material layer 5 is in contact with phase-transition material layer 6. Thermoelectric material layer 5 may be electrically connected to phase-transition material layer 6. Thermoelectric material layer 5 may be disposed so as to face phase-transition material layer 6. Thermoelectric material layer 5 is disposed between first electrode portion 2a and second electrode portion 2b.

Thermoelectric material layer 5 may have sensitivity to the wavelength (detection wavelength) of the electromagnetic wave to be detected by electromagnetic wave detector 100. Thus, when thermoelectric material layer 5 is irradiated with the electromagnetic wave having the detection wavelength, resistance changes upon occurrence of a temperature difference in thermoelectric material layer 5. In other words, when thermoelectric material layer 5 is irradiated with the electromagnetic wave having the detection wavelength, a voltage is generated in thermoelectric material layer 5. This is referred to as the Seebeck effect. Thermoelectric material layer 5 is preferably configured such that a current flows through thermoelectric material layer 5 upon injection of charges into thermoelectric material layer 5 from phase-transition material layer 6.

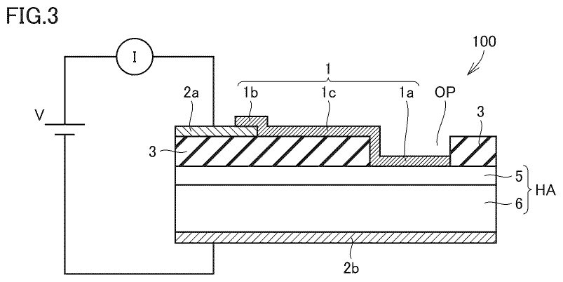

When a current flows through thermoelectric material layer 5 upon change in resistance of phase-transition material layer 6, a temperature change occurs in thermoelectric material layer 5. This is referred to as the Peltier effect. Thermoelectric material layer 5 is preferably disposed to bring a heat generation portion, which generates heat due to the Peltier effect, into thermal contact with phase-transition material layer 6. More preferably, thermoelectric material layer 5 is disposed such that the heat generation portion that generates heat due to the Peltier effect is in direct contact with phase-transition material layer 6. Phase-transition material layer 6 is preferably configured such that the resistance value of phase-transition material layer 6 decreases upon irradiation with an electromagnetic wave. Thermoelectric material layer 5 is desirably disposed such that the resistance of phase-transition material layer 6 changes further by a resultant temperature change. Specifically, when phase-transition material layer 6 whose resistance decreases upon temperature rise is used, the following configuration is desirable: a current flows through thermoelectric material layer 5 by irradiation with an electromagnetic wave, the side of thermoelectric material layer 5 which is in contact with phase-transition material layer 6 generates heat, and the opposite side is cooled. As long as the above configuration is provided, phase-transition material layer 6 and thermoelectric material layer 5 may be disposed in reverse order or may have the structure as shown in FIG. 3.

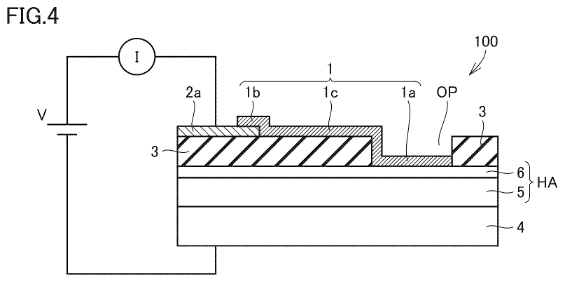

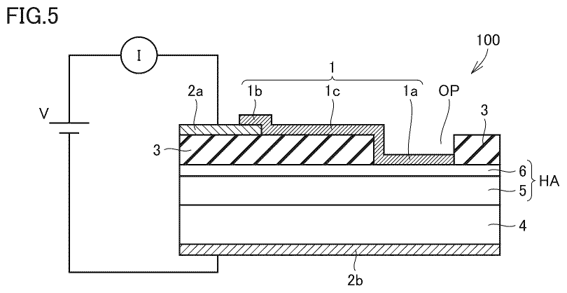

These structures may be disposed on a semiconductor layer 4 as shown in FIGS. 4 and 5. In this case, electromagnetic wave detector 100 further includes semiconductor layer 4. Heat-absorbing layer HA is disposed on semiconductor layer 4. When semiconductor layer 4 having a high conductivity, thermoelectric material layer 5, and phase-transition material layer 6 are used as shown in FIG. 4, second electrode portion 2b may not be provided as long as a current or a voltage for detecting an electromagnetic wave can be extracted. In FIG. 5, second electrode portion 2b is disposed on the bottom side of semiconductor layer 4. Second electrode portion 2b is electrically connected to semiconductor layer 4.

Ammeter I is electrically connected between first electrode portion 2a and second electrode portion 2b. Ammeter I is an ammeter I for detecting a current change that has occurred upon irradiation of electromagnetic wave detector 100 with an electromagnetic wave. Electromagnetic wave detector 100 is configured to detect the electromagnetic wave as ammeter I detects a change in the current flowing between first electrode portion 2a and second electrode portion 2b. Herein, a voltmeter may be used in place of ammeter I, and in such a case, electromagnetic wave detector 100 is configured to detect the electromagnetic wave as the voltmeter detects a voltage change that has occurred between first electrode portion 2a and second electrode portion 2b.

As shown in FIG. 2, the end of two-dimensional material layer 1 has a rectangular shape in plan view. The shape of the end of two-dimensional material layer 1 is not limited to the rectangular shape and may be, for example, a triangular shape or a comb shape. Although not shown, when the end of two-dimensional material layer 1 has the comb shape, first portion 1a may have a plurality of ends electrically connected to phase-transition material layer 6. In FIG. 2, the end of two-dimensional material layer 1 is entirely in contact with phase-transition material layer 6. Thus, the end of two-dimensional material layer 1 is entirely configured as first portion 1a. Although not shown, a part of the end of two-dimensional material layer 1 may be in contact with phase-transition material layer 6, and the other part of the end of two-dimensional material layer 1 may be in contact with insulating film 3. In other words, a part of the end of two-dimensional material layer 1 may be configured as first portion 1a, and the other part of the end of two-dimensional material layer 1 may be configured as third portion 1c. Although not shown, the end of two-dimensional material layer 1 may not be configured as first portion 1a as long as a part of two-dimensional material layer 1 is in contact with phase-transition material layer 6 at first portion 1a.

Next, the configurations of two-dimensional material layer 1, first electrode portion 2a, second electrode portion 2b, insulating film 3, semiconductor layer 4, thermoelectric material layer 5, and phase-transition material layer 6 will be described in detail.

### <Configuration of Two-Dimensional Material Layer 1>

Two-dimensional material layer 1 is, for example, a monolayer graphene. The monolayer graphene is a monoatomic layer of two-dimensional carbon crystal. The graphene has a plurality of carbon atoms arranged in the respective chains arranged in a hexagonal shape. The absorptivity of the graphene is as low as 2.3%. Specifically, the absorptivity of the graphene is 2.3%. Two-dimensional material layer 1 may be a multilayer graphene with stacked graphene layers. The lattice vectors of the respective hexagonal lattices of graphene in the multilayer graphene may have a matched or unmatched orientation. The lattice vectors of the respective hexagonal lattices of graphene in the multilayer graphene may have an exactly matched orientation. Two-dimensional material layer 1 may be a graphene doped with p-type or n-type impurities.

For example, a band gap is formed in two-dimensional material layer 1 as two or more graphene layers are stacked. In other words, the size of the band gap can be adjusted by changing the number of stacked graphene layers. This allows two-dimensional material layer 1 to have the wavelength selection effect of selecting an electromagnetic wave (detection wavelength) to be photoelectrically converted. For example, the mobility in the channel region decreases with an increasing number of graphene layers of the multilayer graphene. On the other hand, the influence of photocarriers scattering from a substrate is suppressed with an increasing number of graphene layers of the multilayer graphene, resulting in a decrease in noise of electromagnetic wave detector 100. Electromagnetic wave detector 100 with two-dimensional material layer 1 including the multilayer graphene thus has improved electromagnetic wave detection sensitivity because optical absorption is increased. Alternatively, the multilayer graphene may be a multilayer graphene with randomly arranged stacking orientation angles, which is referred to as turbostratic stacking. The turbostratic stacking graphene has an approximately equal mobility to that of the monolayer graphene due to its weak interlayer interaction of the graphene and has suppressed electrical disturbance to a graphene base, leading to the effect that mobility can be maintained higher than that of a normal monolayer graphene.

A nanoribbon-shaped graphene (graphene nanoribbon) may be used as two-dimensional material layer 1. Two-dimensional material layer 1 may be a graphene nanoribbon alone. Two-dimensional material layer 1 may have a structure in which a plurality of graphene nanoribbons are stacked. Two-dimensional material layer 1 may have a structure in which graphene nanoribbons arc periodically arranged on a plane. When two-dimensional material layer 1 has the structure in which graphene nanoribbons are periodically arranged, plasmon resonance occurs in the graphene nanoribbons, leading to improved sensitivity of electromagnetic wave detector 100. The structure in which graphene nanoribbons are periodically arranged may also be referred to as a graphene metamaterial. In other words, electromagnetic wave detector 100 including the graphene metamaterial as two-dimensional material layer 1 exhibits the effects described above. Alternatively, holes may be periodically formed in the graphene. Since plasmon resonance occurs depending on the size or the period of the holes also in this case, absorption increases at a specific wavelength, leading to improved sensitivity of electromagnetic wave detector 100. Examples of the shape of the hole include a perfect circle, an ellipse, a square, and a rectangle. The period may be a one-dimensional period, a two-dimensional period, a dual period, or a period with asymmetric property.

An end of two-dimensional material layer 1 may be a graphene nanoribbon. In this case, the graphene nanoribbon has a band gap, and accordingly, a Schottky junction is formed in the junction region between the graphene nanoribbon and phase-transition material layer 6.

As second portion 1b of two-dimensional material layer 1 is brought into contact with first electrode portion 2a, two-dimensional material layer 1 is doped with carriers from first electrode portion 2a. For example, when two-dimensional material layer 1 is the graphene and first electrode portion 2a is gold (Au), the carriers are holes. Second portion 1b that is in contact with first electrode portion 2a is doped with holes due to a difference in work function between graphene and gold (Au). As electromagnetic wave detector 100 is driven in the electron conduction state with second portion 1b doped with holes, the mobility of electrons flowing in the channel decreases due to the influence of the holes. This increases the contact resistance between two-dimensional material layer 1 and first electrode portion 2a. In particular, when all regions of two-dimensional material layer 1 are formed of the monolayer graphene, a large amount (doping amount) of carriers arc injected into two-dimensional material layer 1 from first electrode portion 2a. This results in a remarkable decrease in the mobility of the electric field effect of electromagnetic wave detector 100. When all the regions of two-dimensional material layer 1 are formed of the monolayer graphene, thus, the performance of electromagnetic wave detector 100 decreases.

The amount of carriers with which the multilayer graphene is doped from first electrode portion 2a is smaller than the amount of carriers with which the monolayer graphene is doped from first electrode portion 2a. Thus, as first portion 1a and second portion 1b, which are easily doped with carriers, are formed of the multilayer graphene, an increase in the contact resistance between two-dimensional material layer 1 and first electrode portion 2a can be suppressed. This can suppress a decrease in mobility of the electric field effect of electromagnetic wave detector 100, leading to improved performance of electromagnetic wave detector 100.

<Configurations of First Electrode Portion 2a and Second Electrode Portion 2b>

The material of each of first electrode portion 2a and second electrode portion 2b may be any material as long as it is a conductor. The material of each of first electrode portion 2a and second electrode portion 2b may include, for example, at least any of gold (Au), silver (Ag), copper (Cu), aluminum (Al), nickel (Ni), chromium (Cr), and palladium (Pd). An adhesion layer (not shown) may be provided between first electrode portion 2a and insulating film 3 or between second electrode portion 2b and semiconductor layer 4. The adhesion layer is configured for higher adhesion. The material of the adhesion layer includes, for example, a metallic material such as chromium (Cr), nickel (Ni), or titanium (Ti).

### <Configuration of Insulating Film 3>

The material of insulating film 3 is, for example, a silicon oxide (SiO₂). The material of insulating film 3 is not limited to the silicon oxide and may be, for example, tetraethyl orthosilicate (Si(OC₂H₅)₄), silicon nitride (Si₃N₄), hafnium oxide (HfO₂), aluminum oxide (Al₂O₃), nickel oxide (NiO), boron nitride (BN), or a siloxane-based polymer material. For example, the boron nitride (BN) is similar to the graphene in atomic arrangement. Thus, when the boron nitride (BN) is in contact with two-dimensional material layer 1 made of graphene, a decrease in the electron mobility of two-dimensional material layer 1 is suppressed. For this reason, the boron nitride (BN) is suitable for insulating film 3 serving as a base film disposed below two-dimensional material layer 1.

The thickness of insulating film 3 is not particularly limited as long as first electrode portion 2a is electrically insulated from phase-transition material layer 6 and no tunnel current is generated between first electrode portion 2a and phase-transition material layer 6. The insulating layer may not be disposed below two-dimensional material layer 1.

### <Configuration of Semiconductor Layer 4>

The material of semiconductor layer 4 is, for example, a semiconductor material such as silicon (Si). Specifically, semiconductor layer 4 is, for example, a silicon substrate doped with impurities.

Semiconductor layer 4 may have a multilayer structure. Semiconductor layer 4 may be a pn junction photodiode, a pin photodiode, a Schottky photodiode, or an avalanche photodiode. Semiconductor layer 4 may be a phototransistor.

Although the present embodiment has described the case where the material of semiconductor layer 4 is a silicon substrate, the material of semiconductor layer 4 may be any other material. Examples of the material of semiconductor layer 4 include silicon (Si), germanium (Ge), a compound semiconductor such as a group III-V semiconductor or a group II-V semiconductor, mercury cadmium telluride (HgCdTe), iridium antimonide (InSb), lead selenide (PbSe), lead sulfide (PbS), cadmium sulfide (CdS), gallium nitride (GaN), silicon carbide (SiC), gallium phosphide (GaP), indium gallium arsenide (InGaAs), indium arsenide (InAs), gallium antimonide (GaSb), and indium gallium arsenide (InGaAs). Semiconductor layer 4 may be a substrate including a quantum well or quantum dots. The material of semiconductor layer 4 may be a Type II superlattice. The material of semiconductor layer 4 may be the material alone described above or a combination of the materials described above.

Semiconductor layer 4 is desirably doped with impurities so as to have a resistivity of 100 Ω·cm or less. The reading speed (mobility speed) of photocarriers in semiconductor layer 4 is improved as semiconductor layer 4 is doped at high concentration, leading to an improved response speed of electromagnetic wave detector 100.

Semiconductor layer 4 desirably has a thickness of 10 um or less. The deactivation of photocarriers decreases as the thickness of semiconductor layer 4 decreases.

In the present embodiment, the heat-absorbing layer is composed of thermoelectric material layer 5 and phase-transition material layer 6. Preferably, thermoelectric material layer 5 and phase-transition material layer 6 are connected in series with each other and are configured such that a current flows through two-dimensional material layer 1 and second electrode portion 2b connected to each other in irradiation with an electromagnetic wave. These layers may not be configured to always allow a current to flow when the Seebeck effect of thermoelectric material layer 5 is utilized.

### <Configuration of Thermoelectric Material Layer 5>

The material of thermoelectric material layer 5 may be determined appropriately as long as it is a material that converts thermal energy, produced when a temperature difference is provided to the material, into electrical energy. The material of thermoelectric material layer 5 includes, for example, at least any of p-type bismuth telluride, n-type bismuth telluride, bismuth-telluride-based thermoelectric semiconductor material, telluride-based thermoelectric semiconductor material, antimony-telluride-based thermoelectric semiconductor material, zinc-antimony-based thermoelectric semiconductor material, silicon-germanium-based thermoelectric semiconductor material, selenide-based thermoelectric semiconductor material, silicide-based thermoelectric semiconductor material, oxide-based thermoelectric semiconductor material, Heusler material, oxide material, sulfide-based material, skutterudite-based material, and chalcogenide-based material. An example of the bismuth-telluride-based thermoelectric semiconductor material is bismuth telluride (Bi₂Te₃). Examples of the telluride-based thermoelectric semiconductor material include germanium telluride (GeTe), magnesium telluride (MgTe), and lead telluride (PbTe). An example of the antimony-telluride-based thermoelectric semiconductor material is an antimony-telluride compound (Sb₂Te₃). Examples of the zinc-antimony-based thermoelectric semiconductor material include zinc antimonides (ZnSb, Zn₃Sb₂, and Zn₄Sb₃). An example of the silicon-germanium-based thermoelectric semiconductor material is silicon germanium (SiGe). Examples of the selenide-based thermoelectric semiconductor material include bismuth selenide (III) (Bi₂Se₃), Cu₂Se, and SnSe. Examples of the silicide-based thermoelectric semiconductor material include iron silicide (β-FeSi₂), chromium silicide (CrSi₂), manganese silicide (MnSi_{1.73}), and magnesium silicide (Mg₂Si). Examples of the Heusler material include FeVAl, FeVAlSi, and FeVTiAl. Examples of the oxide-based thermoelectric semiconductor material include BiCuSeO and Co:BiCuSeO. The material of thermoelectric material layer 5 is desirably any of p-type bismuth telluride, n-type bismuth telluride, bismuth-telluride-based thermoelectric semiconductor material, and silicide-based thermoelectric semiconductor material. Desirably, the carrier of the p-type bismuth telluride is a hole, the Seebeck coefficient of the p-type bismuth telluride is a positive value, and the composition of the p-type bismuth telluride is represented by Bi_{X}Te₃Sb₂—X (0<X ≤0.6). Desirably, the carrier of the n-type bismuth telluride is an electron, the Seebeck coefficient of the n-type bismuth telluride is a negative value, and the composition of the n-type bismuth telluride is represented by Bi₂Te₃—YSe_{Y} (0<Y≤3). The p-type bismuth telluride and n-type bismuth telluride described above are desirably used in a pair. The p-type bismuth telluride and n-type bismuth telluride described above may be used in pairs by being connected in series with each other. In this case, electromagnetic wave detector 100 has improved sensitivity because a voltage generated by thermoelectric conversion can be increased. Thermoelectric material layer 5 may be a layer obtained by stacking or mixing different thermoelectric materials. Impurities may be added to the material described above to control the p-type and n-type polarities or control an electrical conductivity. Thermal conductivity may be controlled by controlling the particle size of the material.

The material of thermoelectric material layer 5 is not limited to the thermoelectric materials described above and may be any substance exhibiting the thermoelectric generation effect. Specifically, it suffices that the material of thermoelectric material layer 5 is any thermoelectric material that causes a potential difference due to a temperature difference between substances or causes a temperature difference between substances as a current flows. Since the electromagnetic wave acts merely as a source of heat in the thermoelectric conversion effect, the thermoelectric conversion effect basically does not depend on wavelength. Thus, thermoelectric material layer 5 has sensitivity to wide-band electromagnetic waves.

In thermoelectric material layer 5, the heat generation portion and the cooling portion are preferably apart from each other so as not to be interfered by the temperature of its counterpart to easily cause a temperature difference.

### <Configuration of Phase-Transition Material Layer 6>

The material of phase-transition material layer 6 is desirably a material that undergoes a phase transition and changes its resistance for the electromagnetic wave (temperature) of the detection wavelength. Specifically, a smart radiation device, a Mott insulator, a metal-semiconductor phase transition material, a metal-insulator phase transition material, a ceramic material that absorbs heat along with crystal structure phase transition or magnetic phase transition, a titanium oxide nanoparticle having photoinduced phase transition, a chalcogenide alloy (Ge₂Sb₂Te₅: GST) of germanium (Ge), antimony (Sb), and tellurium (Te), Ge₂Sb₂Se₄Te₁ (GSST), or a TaS two-dimensional material layer is used.

These consist mainly of oxides of transition metals, and oxides with a perovskite structure are particularly desirable. Examples of the oxide of the transition metal include ReNiO₃ (Re is a rare-earth element), M1(1-(x+y))M2ₓM3_{y}MnO₃ (M1 is La, Pr, Sc, In, Nd, or Sm, M2 is an alkaline earth metal, M3 is an alkaline earth metal not identical to M2, 0≤x≤1, 0≤y≤1), La_{1-x-y}SrₓCa_{y}MnO₃ (0≤x≤1, 0≤y≤1), Ca₂Ru₁₋ₓMₓO₄ (M is Mn or Fe, 0≤x≤1), and VO₂. The oxide of the transition metal is a material whose emissivity changes before and after a specific temperature range. The temperature of the temperature region and temperature width thereof need to be selected appropriately according to use.

Examples of the ceramic material that absorbs heat along with crystal structure phase transition, magnetic phase transition, or the like include a vanadium dioxide (VO₂) and a lithium-vanadium composite oxide (LiVO₂).

Although the thickness of phase-transition material layer 6 can be set as appropriate, phase-transition material layer 6 is desirably disposed so as to have a high resistance when being not irradiated with an electromagnetic wave and have a low resistance when being irradiated with an electromagnetic wave.

### <Method of Manufacturing Electromagnetic Wave Detector 100>

Next, a method of manufacturing electromagnetic wave detector 100 according to Embodiment 1 will be described with reference to FIG. 5.

The method of manufacturing electromagnetic wave detector 100 includes a preparation step, a second electrode portion forming step, a thermoelectric material layer forming step, a phase-transition material layer forming step, an insulating film forming step, a first electrode portion forming step, an opening forming step, and a two-dimensional material layer forming step.

First, the preparation step is performed. In the preparation step, a flat semiconductor substrate containing silicon (Si) or the like is prepared as semiconductor layer 4, as shown in FIG. 5. The material of the semiconductor substrate may be a material having sensitivity to a predetermined detection wavelength.

Subsequently, the second electrode portion forming step is performed. In the second electrode portion forming step, a protective film is formed on a first surface of semiconductor layer 4. The protective film is, for example, a resist. With the first surface of semiconductor layer 4 protected by the protective film, second electrode portion 2b is formed on a second surface of semiconductor layer 4. Before the formation of second electrode portion 2b, an adhesion layer (not shown) may be formed in the region of the second surface of semiconductor layer 4 where second electrode portion 2b is formed.

Subsequently, the thermoelectric material layer forming step is performed. In the thermoelectric material layer forming step, thermoelectric material layer 5 is formed on the first surface of semiconductor layer 4. The method of forming the thermoelectric material layer may be determined as appropriate. For example, when thermoelectric material layer 5 is formed of a polymer-based material, thermoelectric material layer 5 is formed by forming a polymer film by spin coating or the like and then processing the polymer film by photolithography. When the material of thermoelectric material layer 5 is different from the polymer-based material, thermoelectric material layer 5 is formed by epitaxial growth, molecular beam epitaxial growth (MBE), sputtering, vapor deposition, metal organic decomposition (MOD) (MOD coating), atomic layer deposition (ALD), or any other method, and then, thermoelectric material layer 5 is patterned by photolitorgaphy. Alternatively, a method referred to as lift-off may be used. In the method referred to as lift-off, thermoelectric material layer 5 is formed using a resist mask as a mask, and then, the resist mask is removed.

Subsequently, phase-transition material layer 6 is formed. In the phase-transition material layer forming step, phase-transition material layer 6 is formed on thermoelectric material layer 5. The method of forming phase-transition material layer 6 may be determined as appropriate. For example, when phase-transition material layer 6 is formed of the polymer-based material, phase-transition material layer 6 is formed by forming a polymer film by spin coating or the like and then processing the polymer film by photolithography. When the material of phase-transition material layer 6 is different from the polymer-based material, phase-transition material layer 6 is formed by epitaxial growth, molecular beam epitaxial growth (MBE), sputtering, vapor deposition, metal organic decomposition (MOD) (MOD coating), atomic layer deposition (ALD), or any other method, and then, phase-transition material layer 6 is patterned by photolithography. Alternatively, a method referred to as lift-off may be used. In the method referred to as lift-off, phase-transition material layer 6 is formed using a resist mask as a mask, and then, the resist mask is removed.

Subsequently, the insulating film forming step is performed. In the insulating film forming step, insulating film 3 is formed on a surface of phase-transition material layer 6. For example, the method of forming insulating film 3 may be chemical vapor deposition (CVD) or sputtering.

Subsequently, the first electrode portion forming step is performed. In the first electrode portion forming step, first electrode portion 2a is formed on insulating film 3. Before the formation of first electrode portion 2a, an adhesion layer may be formed in the region of insulating film 3 where first electrode portion 2a is formed.

For example, the following process is used as the method of forming first electrode portion 2a. First, a resist mask is formed on insulating film 3 by photoengraving, electron beam (EB) lithography, or the like. An open portion is formed in the region of the resist mask where first electrode portion 2a is formed. Subsequently, a film of metal or the like that turns into first electrode portion 2a is formed on the resist mask. Vapor deposition, sputtering, or any other method is used to form the film. At this time, the film is formed so as to extend from the inside of the open area of the resist mask to the upper surface of the resist mask. Subsequently, the resist mask is removed together with a part of the film. Another part of the film disposed in the open area of the resist mask remains on insulating film 3 to turn into first electrode portion 2a. The method described above is a method generally referred to as lift-off.

Any other method may be used as the method of forming first electrode portion 2a. For example, a film, such as a metallic film, that turns into first electrode portion 2a is first formed on insulating film 3. Subsequently, a resist mask is formed on the film by photolithography. The resist mask is formed to cover the region where first electrode portion 2a is formed but is not formed in any region other than the region where first electrode portion 2a is formed. Subsequently, the film is partially removed using the resist mask as a mask by wet etching or dry etching. As a result, a part of the film remains below the resist mask. A part of this film turns into first electrode portion 2a. Subsequently, the resist mask is removed. First electrode portion 2a may be formed as described above.

Subsequently, the opening forming step is performed. In the opening forming step, opening OP is formed in insulating film 3. Specifically, a resist mask (not shown) is formed on insulating film 3 by photoengraving, electron beam lithography, or the like. An open portion is formed in the region of the resist mask in insulating film 3 where opening OP is formed. Subsequently, insulating film 3 is etched using the resist mask as an etching mask. The etching technique can be selected as appropriate from wet etching and dry etching described above. The resist mask is removed after etching. The opening forming step may be performed before the first electrode portion forming step.

Subsequently, the two-dimensional material layer forming step is performed. In the two-dimensional material layer forming step, two-dimensional material layer 1 is formed such that first electrode portion 2a, insulating film 3, and phase-transition material layer 6 exposed inside opening OP are covered with two-dimensional material layer 1. The method of forming two-dimensional material layer 1 is not particularly limited. Two-dimensional material layer 1 may be formed by, for example, epitaxial growth or screen printing. Two-dimensional material layer 1 may be formed by transferring and attaching a two-dimensional material film formed by CVD in advance. Two-dimensional material layer 1 may be formed by transferring and attaching a film-shaped two-dimensional material film peeled off by mechanical peeling or the like.

After the formation of two-dimensional material layer 1, a resist mask is formed on two-dimensional material layer 1 by photoengraving or the like. The resist mask is formed so as to cover the region where two-dimensional material layer 1 is formed and expose the other region. Subsequently, two-dimensional material layer 1 is etched using the resist mask as an etching mask. The etching technique is, for example, dry etching using oxygen plasma. Subsequently, the resist mask is removed. Consequently, two-dimensional material layer 1 shown in FIG. 1 is formed.

Electromagnetic wave detector 100 is manufactured through the steps described above.

Although two-dimensional material layer 1 is formed on first electrode portion 2a by the manufacturing method described above, first electrode portion 2a may be formed to overlap part of two-dimensional material layer 1 after the formation of two-dimensional material layer 1 on insulating film 3. Note that care should be exercised in the formation of first electrode portion 2a so as not to damage two-dimensional material layer 1 through the process of forming first electrode portion 2a. For example, first electrode portion 2a is formed with any region other than the region of two-dimensional material layer 1, on which first electrode portion 2a is overlaid, covered in advance with a protective film or the like, thus suppressing damage by the process of forming first electrode portion 2a.

### <Operating Principle of Electromagnetic Wave Detector 100>

Next, the operating principle of electromagnetic wave detector 100 according to Embodiment 1 will be described with reference to FIG. 1.

As shown in FIG. 1, first, ammeter I or the ammeter (not shown) is electrically connected between first electrode portion 2a and second electrode portion 2b. First electrode portion 2a, two-dimensional material layer 1, phase-transition material layer 6, thermoelectric material layer 5, and second electrode portion 2b are electrically connected in order. Ammeter I or the voltmeter (not shown) measures a voltage of a current flowing through two-dimensional material layer 1 or the current. At this time, a bias voltage V is applied to two-dimensional material layer 1. When bias voltage V is not applied to two-dimensional material layer 1, a dark current is zero because no voltage is applied. In other words, electromagnetic wave detector 100 is turned off. As the Schottky junction or pn junction is formed at the interface between two-dimensional material layer 1 and phase-transition material layer 6, at the interface between phase-transition material layer 6 and thermoelectric material layer 5, or in thermoelectric material layer 5, a dark current can be made zero to turn off electromagnetic wave detector 100 even when bias voltage V is applied.

Next, phase-transition material layer 6 is irradiated with an electromagnetic wave. The temperature of phase-transition material layer 6 rises due to the heat of the electromagnetic wave to cause a phase transition in a phase transition material, resulting in a decrease in the resistance value of phase-transition material layer 6. Thus, charges are injected into thermoelectric material layer 5 from phase-transition material layer 6. This causes a current to flow through thermoelectric material layer 5, thereby generating a temperature difference between the upper portion and the lower portion of thermoelectric material layer 5 due to the Peltier effect. The upper portion of thermoelectric material layer 5 generates heat, and the lower portion of thermoelectric material layer 5 is cooled. Since the upper portion of thermoelectric material layer 5 is in contact with phase-transition material layer 6, phase-transition material layer 6 is heated further to decrease a resistance value, causing a current to flow further through thermoelectric material layer 5. This phenomenon is repeated until the equilibrium state is attained, generating a large current change. Further, phase-transition material layer 6 is connected to two-dimensional material layer 1 with insulating film 3 in between, and a gate voltage change is caused in a pseudo manner in two-dimensional material layer 1 due to a change in the resistance value of phase-transition material layer 6. This modulates the fermi level of two-dimensional material layer 1, and the resistance value of two-dimensional material layer 1 changes. This is referred to as a photogating effect. Thus, a change in the resistance between first electrode portion 2a and second electrode portion 2b changes the voltage and the current between first electrode portion 2a and second electrode portion 2b. The electromagnetic wave applied to electromagnetic wave detector 100 can be detected by detection of a change in any of voltage and current.

As an electromagnetic wave is applied to one surface of thermoelectric material layer 5, a temperature change is caused in thermoelectric material layer 5, thus generating a voltage in thermoelectric material layer 5 due to the Seebeck effect. An element may be driven using this voltage without applying bias voltage V. Since a generated voltage is additionally applied to each layer even when bias voltage V is applied, the resistance changes increases further. At this time, the generated voltage brings about the photogating effect, modulating the fermi level of two-dimensional material layer 1 and also changes the resistance value of two-dimensional material layer 1. This increases a photocurrent, resulting in further increased sensitivity of electromagnetic wave detector 100.

Electromagnetic wave detector 100 is not limited to the configuration in which a current change is detected as described above. For example, with a constant current flowing between first electrode portion 2a and second electrode portion 2b, a voltage change between first electrode portion 2a and second electrode portion 2b may be detected at the irradiation of electromagnetic wave detector 100 with an electromagnetic wave. The voltage change between first electrode portion 2a and second electrode portion 2b at the irradiation of electromagnetic wave detector 100 with an electromagnetic wave is a voltage change in two-dimensional material layer 1.

Electromagnetic wave detector 100 described above may be disposed as a first electromagnetic wave detector, and a second electromagnetic wave detector having the same configuration as that of the first electromagnetic wave detector may be disposed further. The first electromagnetic wave detector is disposed in a space irradiated with the electromagnetic wave. The second electromagnetic wave detector is disposed in a space shielded from the clectromagnetic wave. The electromagnetic wave may be detected by detecting a difference between a current of the first electromagnetic wave detector and a current of the second electromagnetic wave detector. The electromagnetic wave may be detected by detecting a difference in voltage between the first electromagnetic wave detector and the second electromagnetic wave detector.

### <Operation of Electromagnetic Wave Detector 100>

Next, a specific operation of electromagnetic wave detector 100 according to Embodiment 1 will be described with reference to FIG. 1.

Ammeter I is connected to the junction between two-dimensional material layer 1 and heat-absorbing layer HA composed of phase-transition material layer 6 and thermoelectric material layer 5. The detection wavelength of electromagnetic wave detector 100 depends on the absorption wavelength of heat-absorbing layer HA.

With no electromagnetic wave applied, a dark current is suppressed to enable OFF operation when the Schottky junction or the pn junction is formed between the graphene and heat-absorbing layer HA or inside heat-absorbing layer HA. As the electromagnetic wave having the detection wavelength enters heat-absorbing layer HA, a temperature change occurs in phase-transition material layer 6, leading to a resistance change. Also, a temperature difference occurs in thermoelectric material layer 5, generating a voltage due to the Seebeck effect. When heat-absorbing layer HA is configured by series connection between phase-transition material layer 6 and thermoelectric material layer 5, application of a voltage between the graphene and heat-absorbing layer HA causes a current to flow through thermoelectric material layer 5 upon change of the resistance value of phase-transition material layer 6. This brings about the Peltier effect to increase the temperature difference of thermoelectric material layer 5. At this time, the configuration in which the high-temperature side of thermoelectric material layer 5 is in contact with phase-transition material layer 6 can further reduce a resistance value of phase-transition material layer 6. This generates a large current. Also, a resistance change of phase-transition material layer 6 and a voltage change of thermoelectric material layer 5 change the fermi level of the graphene via insulating film 3 due to the photogating effect, resulting in a change in the resistance value of two-dimensional material layer 1. Combination of these effects can lead to a significant current change.

Further, when the speeds of temperature change of thermoelectric material layer 5 and resistance change of phase-transition material layer 6 are set to be as short as possible, a time between entrance of an electromagnetic wave to electromagnetic wave detector 100 and occurrence of a resistance change in two-dimensional material layer 1 becomes shorter. This suppresses a delay in amplification of photocarriers, increasing a response speed of electromagnetic wave detector 100.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, heat-absorbing layer HA composed of thermoelectric material layer 5 and phase-transition material layer 6 is electrically connected to two-dimensional material layer 1, as shown in FIG. 1. In heat-absorbing layer HA, the resistance value of phase-transition material layer 6 decreases due to heat generation by irradiation with an electromagnetic wave, and a voltage is generated in thermoelectric material layer 5 due to a resultant temperature difference. A current flowing through thermoelectric material layer 5 increases due to a decrease in resistance of phase-transition material layer 6, increasing a temperature difference of thermoelectric material layer 5. As a result, phase-transition material layer 6 that is in contact with the heat generation portion of thermoelectric material layer 5 is heated further, resulting in a further decrease in resistance value. The above is repeated until the equilibrium state is attained. This changes the resistance value of heat-absorbing layer HA and modulates the fermi level of two-dimensional material layer 1 connected to heat-absorbing layer HA with insulating film 3 in between, also changing the resistance value of two-dimensional material layer 1. Through the above, a voltage change and a current change occur in electromagnetic wave detector 100. The resistance change of phase-transition material layer 6 and the voltage change of thermoelectric material layer 5 due to a temperature difference are caused by a temperature change and do not depend on the wavelength of the electromagnetic wave. Thus, the sensitivity of electromagnetic wave detector 100 less depends on the quantum efficiency of a semiconductor than a detector including a conventional semiconductor. For this reason, even at a wavelength at which the quantum efficiency of the semiconductor layer decreases, a decrease in sensitivity of electromagnetic wave detector 100 is suppressed. Thus, electromagnetic wave detector 100 has improved sensitivity. Specifically, higher sensitivity exceeding 100% quantum efficiency is enabled.

More specifically, the amount of current change in two-dimensional material layer 1 due to the photogating effect resulting from a resistance change of heat-absorbing layer HA is greater than the amount of current change in a normal semiconductor. In particular, in two-dimensional material layer 1, a large current change is caused for a small gate voltage change compared with a normal semiconductor. For example, when a monolayer graphene is used as two-dimensional material layer 1, the thickness of two-dimensional material layer 1, which is the thickness of one atomic layer, is extremely thin. Also, the mobility of electrons in the monolayer graphene is high. In this case, the amount of current change in two-dimensional material layer 1, which is calculated from the mobility of electrons, thickness, and the like in two-dimensional material layer 1, is several hundreds of times to several thousands of times larger than the amount of current change in a normal semiconductor. The bias voltage applied to two-dimensional material layer 1 also changes due to the resistance change of heat-absorbing layer HA described above. The effect that application of a bias voltage to electromagnetic wave detector 100 in a pseudo manner greatly changes the fermi level of two-dimensional material layer 1 and changes the energy barrier between two-dimensional material layer 1 and heat-absorbing layer HA is referred to as the photobiasing effect.

The photobiasing effect greatly improves the efficiency of extracting a detection current in two-dimensional material layer 1. The photobiasing effect does not directly enhance the quantum efficiency of a photoelectric conversion material unlike a normal semiconductor but increases the amount of current change due to entrance of an electromagnetic wave. Thus, the quantum efficiency of electromagnetic wave detector 100, calculated from the differential current due to the entrance of the electromagnetic wave, can exceed 100%. Therefore, the detection sensitivity to an electromagnetic wave by electromagnetic wave detector 100 according to the present embodiment is higher than that of a semiconductor electromagnetic wave detector or a graphene electromagnetic wave detector to which the photobiasing effect is not applied.

In other words, the photogating effect, caused by a change in the gate voltage via insulating film 3 which results from a resistance change of heat-absorbing layer HA, and the photobiasing effect, caused by a change in the bias voltage applied to two-dimensional material layer 1, occur simultaneously in electromagnetic wave detector 100 according to the present embodiment.

As shown in FIG. 1, two-dimensional material layer 1 is electrically connected to phase-transition material layer 6 at opening OP. Two-dimensional material layer 1 may be joined to phase-transition material layer 6 by the Schottky junction at opening OP. The Schottky junction or pn junction may be formed between phase-transition material layer 6 and thermoelectric material layer 5 or in thermoelectric material layer 5. At this time, no current flows through two-dimensional material layer 1 when a reverse bias is applied to electromagnetic wave detector 100. In other words, a flow of a dark current through two-dimensional material layer 1 can be suppressed. This allows electromagnetic wave detector 100 to be turned off. When a forward bias is applied to two-dimensional material layer 1, a large current change can be obtained by a small voltage change. This improves the sensitivity of electromagnetic wave detector 100. Consequently, improvement in sensitivity of electromagnetic wave detector 100 and OFF operation of electromagnetic wave detector 100 can be achieved simultaneously.

When semiconductor layer 4 is provided as shown in FIGS. 4 and 5, electromagnetic wave detector 100 can also simultaneously detect an electromagnetic wave that has passed through insulating film 3 and heat-absorbing layer HA. As the electromagnetic wave enters semiconductor layer 4, photocarriers are generated in semiconductor layer 4. The photocarriers pass through two-dimensional material layer 1 to be output to first electrode portion 2a. Two-dimensional material layer 1 includes a portion disposed in insulating film 3. Thus, a change in the electrical field due to the photocarriers generated in semiconductor layer 4 is applied to two-dimensional material layer 1 via insulating film 3. The conductivity of two-dimensional material layer 1 due to the photogating effect is easily modulated more greatly than when two-dimensional material layer 1 does not include a portion disposed on insulating film 3. This improves the sensitivity of electromagnetic wave detector 100.

The amount of current change at the irradiation of electromagnetic wave detector 100 with an electromagnetic wave includes a change due to a photoelectric current generated by photoelectric conversion in two-dimensional material layer 1. Thus, the photobiasing effect, photogating effect, and photoelectric conversion described above occur by irradiation of electromagnetic wave detector 100 with an electromagnetic wave. This allows electromagnetic wave detector 100 to detect a current change due to the photobiasing effect, photogating effect, and photoelectric conversion. Therefore, electromagnetic wave detector 100 has improved sensitivity.

As shown in FIG. 1, electromagnetic wave detector 100 is configured to detect an electromagnetic wave as at least any of ammeter I and the voltmeter detects a change in at least any of a voltage of a current flowing between first electrode portion 2a and second electrode portion 2b and the current. This enables detection of an electromagnetic wave using at least any of ammeter I and the voltmeter.

Two-dimensional material layer 1 includes any material selected from the group consisting of graphene, transition metal dichalcogenide, black phosphorus, silicene, graphene nanoribbon, and borophene. Thus, the functions and effects of the present embodiment can be achieved reliably.

Thermoelectric material layer 5 is provided to generate heat as a current flows therethrough to heat phase-transition material layer 6. Thus, a large photocurrent can be obtained for a small resistance change. This improves the sensitivity of electromagnetic wave detector 100.

Silicon (Si) may be used for semiconductor layer 4. Thus, a readout circuit can be formed in semiconductor layer 4. This eliminates the need for additionally forming any other circuit outside electromagnetic wave detector 100.

Second electrode portion 2b is electrically connected to heat-absorbing layer HA or semiconductor layer 4. Thus, an electromagnetic wave can be detected by detection of a change in the current or voltage flowing between first electrode portion 2a and second electrode portion 2b.

Thermoelectric material layer 5 includes at least any of a bismuth-telluride-based thermoelectric semiconductor material, a telluride-based thermoelectric semiconductor material, and a silicon-germanium-based thermoelectric semiconductor material. A large temperature difference can be obtained by using such a material.

Two-dimensional material layer 1 may include any of a monolayer graphene, a multilayer graphene, a turbostratic stacking graphene, or a plurality of two-dimensional material layers, and has a multilayer structure including two or more selected from the group consisting of these materials. For the multilayer, absorptivity is high. For the turbostratic stacking graphene, mobility is high, leading to improved sensitivity.

### Embodiment 2

Next, a configuration of electromagnetic wave detector 100 according to

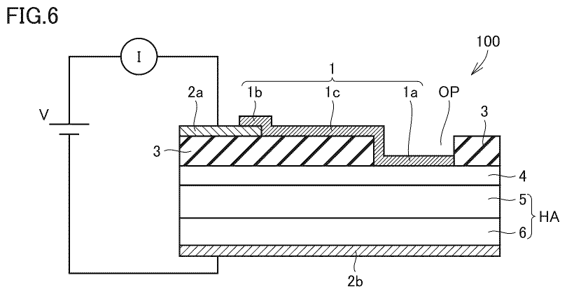

Embodiment 2 will be described with reference to FIG. 6. Unless otherwise described, Embodiment 2 has the same components and the same functions and effects as those of Embodiment 1 described above. Thus, the same components as those of Embodiment 1 described above have the same reference characters allotted, and description thereof will not be repeated.

In electromagnetic wave detector 100 according to the present embodiment, semiconductor layer 4 is disposed between two-dimensional material layer 1 and heat-absorbing layer HA, as shown in FIG. 6. Electromagnetic wave detector 100 according to the present embodiment is different from electromagnetic wave detector 100 according to Embodiment 1 in that semiconductor layer 4 is disposed to be joined to two-dimensional material layer 1.

Semiconductor layer 4 may not be located below insulating film 3, but when it is located below insulating film 3, photocarriers generated when semiconductor layer 4 absorb an electromagnetic wave brings about the photogating effect via insulating film 3.

Semiconductor layer 4 desirably has sensitivity to a wavelength that does not interfere with absorption by heat-absorbing layer HA. Also, semiconductor layer 4 has such a thickness that does not interfere with adsorption by heat-absorbing layer HA.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, semiconductor layer 4 is disposed between heat-absorbing layer HA and two-dimensional material layer 1, as shown in FIG. 6. Thus, the Schottky junction is formed by two-dimensional material layer 1 and semiconductor layer 4. In other words, a dark current flowing through two-dimensional material layer 1 can be suppressed. Thus, noise is suppressed as the dark current of electromagnetic wave detector 100 decreases, leading to higher sensitivity of electromagnetic wave detector 100. When semiconductor layer 4 is disposed below insulating film 3, photocarriers generated by the light absorbed by semiconductor layer 4 cause two-dimensional material layer 1 to exhibit the photogating effect via insulating film 3. This results in improved sensitivity of electromagnetic wave detector 100.

### Embodiment 3

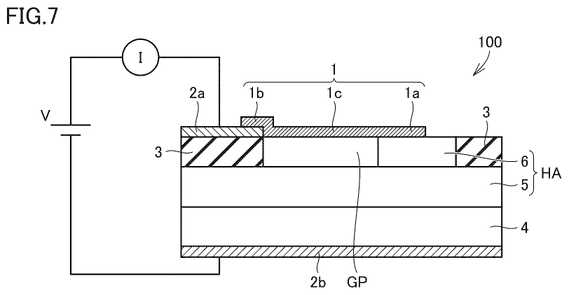

Next, a configuration of electromagnetic wave detector 100 according to Embodiment 3 will be described with reference to FIG. 7. Unless otherwise described, Embodiment 3 has the same components and the same functions and effects as those of Embodiment 1 described above. Thus, the same components as those of Embodiment 1 described above have the same reference characters allotted, and description thereof will not be repeated.

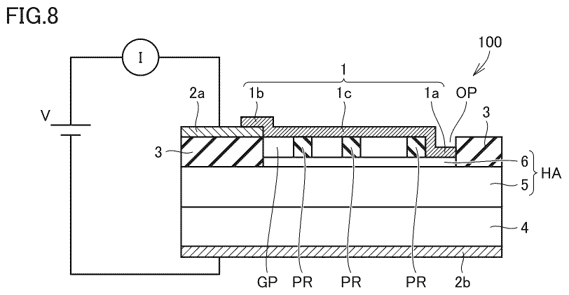

In electromagnetic wave detector 100 according to the present embodiment, an air gap GP is provided below two-dimensional material layer 1, as shown in FIG. 7. Air gap GP is provided between insulating film 3 and two-dimensional material layer 1. Two-dimensional material layer 1 has a surface facing air gap GP. In other words, two-dimensional material layer 1 has a portion disposed apart from insulating film 3, unlike electromagnetic wave detector 100 according to Embodiment 1. Two-dimensional material layer 1 located other than at the junction between first electrode portion 2a and two-dimensional material layer 1 and the junction between heat-absorbing layer HA and two-dimensional material layer 1 preferably faces air gap GP as much as possible. Any other configuration can be employed as long as air gap GP is provided between two-dimensional material layer 1 and the insulating film. Alternatively, as shown in FIG. 8, pillars PR for forming air gap GP may be inserted between two-dimensional material layer 1 and insulating film 3 or heat-absorbing layer HA.

The thickness of air gap GP is not particularly specified as long as the influence of carrier scattering on a surface of two-dimensional material layer 1 or insulating film 3 can be suppressed. However, air gap GP preferably has the smallest possible thickness in order to maximize the influence of the photogating effect due to a resistance change of heat-absorbing layer HA. The influence of the photogating effect increases as air gap GP is thinner, resulting in a larger resistance change of two-dimensional material layer 1.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, air gap GP is provided below two-dimensional material layer 1, as shown in FIG. 7. Air gap GP is provided between insulating film 3 and two-dimensional material layer 1. This can eliminate the influence of the carrier scattering associated with contact between insulating film 3 and two-dimensional material layer 1. As a result, a decrease in mobility of carriers in two-dimensional material layer 1 can be suppressed. This can improve the sensitivity of electromagnetic wave detector 100.

### Embodiment 4

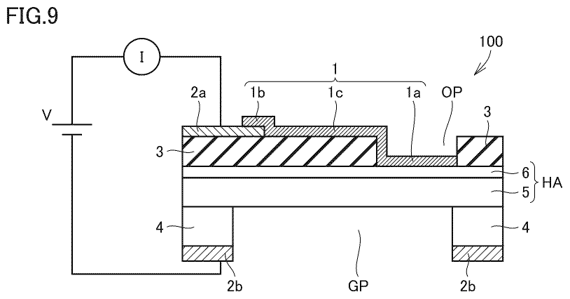

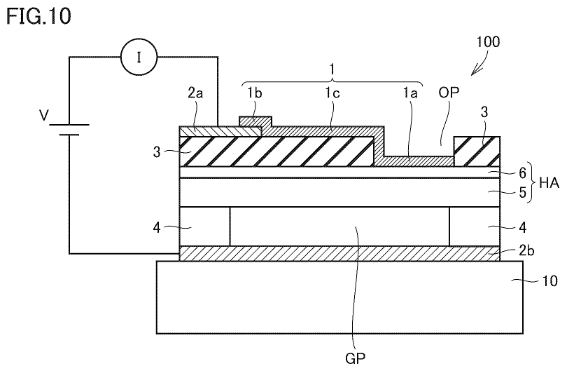

Next, a configuration of clectromagnetic wave detector 100 according to Embodiment 4 will be described with reference to FIGS. 9 and 10. Unless otherwise described, Embodiment 5 has the same components and the same functions and effects as those of Embodiment 1 described above. Thus, the same components as those of Embodiment 1 described above have the same reference characters allotted, and description thereof will not be repeated.

In electromagnetic wave detector 100 according to the present embodiment, air gap GP is provided below heat-absorbing layer HA, as shown in FIG. 9. Heat-absorbing layer HA has a surface facing air gap GP. In other words, heat-absorbing layer HA includes a portion disposed apart from semiconductor layer 4, unlike electromagnetic wave detector 100 according to Embodiment 1. When semiconductor layer 4 is not used, a pillar may be formed using an insulating layer or the like. The material of this insulating layer is, for example, a silicon oxide (SiO₂). Air gap GP is provided below thermoelectric material layer 5. Although air gap GP is provided below thermoelectric material layer 5 in FIG. 9, it may be provided below phase-transition material layer 6. Air gap GP is preferably located below heat-absorbing layer HA other than second electrode portion 2b as much as possible. Any other configuration may be employed as long as air gap GP is provided in heat-absorbing layer HA. Alternatively, a pillar for forming air gap GP may be inserted below heat-absorbing layer HA.

Heat-absorbing layer HA may be formed on another substrate 10 with air gap GP in between, as shown in FIG. 10. In this case, second electrode portion 2b may not have the configuration of FIG. 10 as long as a signal can be read from heat-absorbing layer HA.

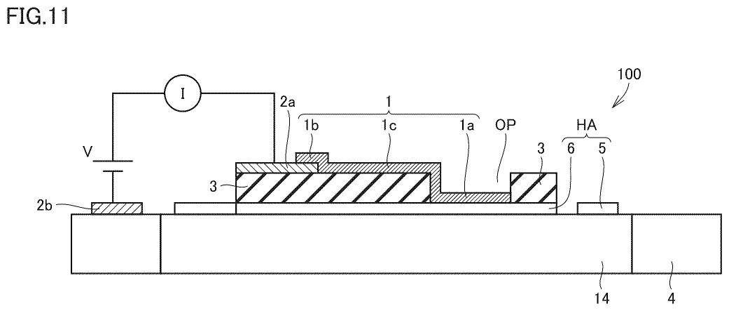

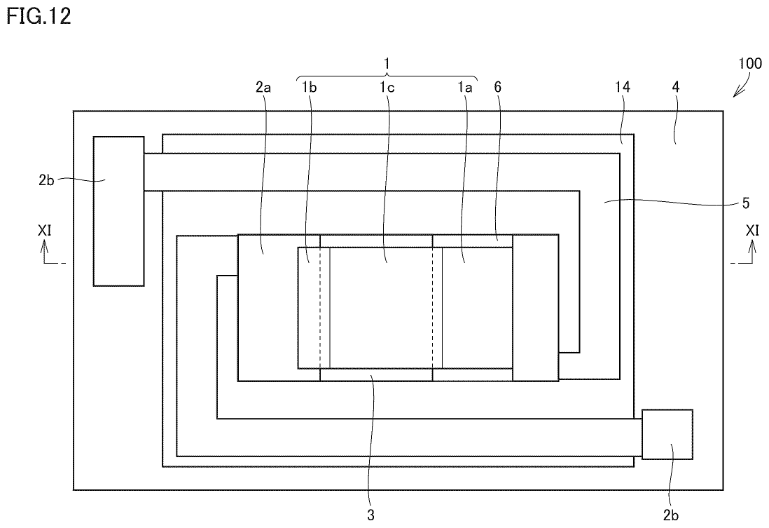

In FIGS. 11 and 12, heat-absorbing layer HA is formed on a hollow 14. Thermoelectric material layer 5 supports phase-transition material layer 6 or the like as the pillar. Thermoelectric material layer 5 is connected to phase-transition material layer 6 and second electrode portion 2b. Hollow 14 is provided below thermoelectric material layer 5. Electromagnetic wave detector 100 has a hollow structure. Hollow 14 is also provided below phase-transition material layer 6. Thermoelectric material layer 5 has a region that is in contact with phase-transition material layer 6 as the heat generation portion, and a region located on the second electrode portion 2b side as the cooling portion. Thermoelectric material layer 5 is preferably as long as possible.

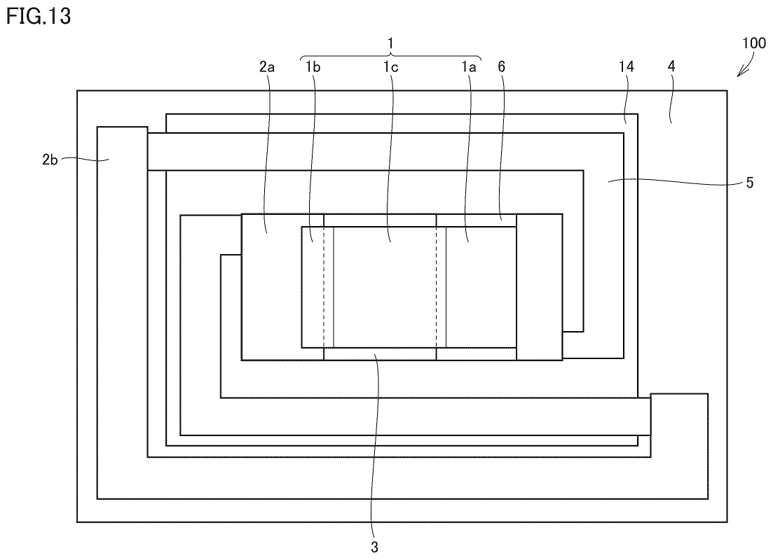

Two second electrode portions 2b are provided in FIG. 12, and a voltage may be applied thereto separately, or the same voltage may be applied thereto. As shown in FIG. 13, the opposite ends of second electrode portion 2b may be connected at the same potential.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, air gap GP is provided below heat-absorbing layer HA, as shown in FIGS. 9 and 10. Thus, the heat insulation performance of heat-absorbing layer HA can be improved, thereby suppressing heat dissipation after irradiation with an electromagnetic wave. As a result, a resistance change associated with a temperature change of heat-absorbing layer HA can be increased. This can improve the sensitivity of electromagnetic wave detector 100.

In FIGS. 11 to 13, since thermoelectric material layer 5 is configured to meander in plan view, the distance between a portion of thermoelectric material layer 5 which is connected to phase-transition material layer 6 and a portion of thermoelectric material layer 5 which is connected to second electrode portion 2b is longer than in a thin film state (a linear state). This easily causes a temperature difference between the portion of thermoelectric material layer 5 which is connected to phase-transition material layer 6 and the portion of thermoelectric material layer 5 which is connected to second electrode portion 2b. As a result, a resistance change associated with a temperature change of heat-absorbing layer HA can be increased. This can improve the sensitivity of electromagnetic wave detector 100.

### Embodiment 5

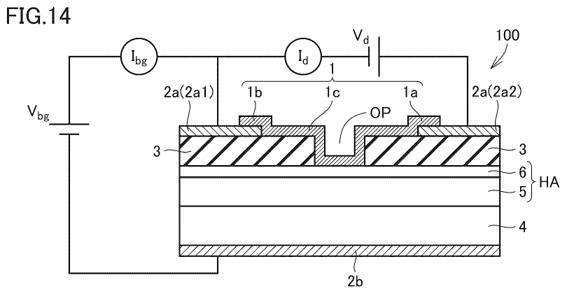

Next, a configuration of electromagnetic wave detector 100 according to Embodiment 5 will be described with reference to FIG. 14. Unless otherwise described, Embodiment 5 has the same components and the same functions and effects as those of Embodiment 1 described above. Thus, the same components as those of Embodiment 1 described above have the same reference characters allotted, and description thereof will not be repeated.

As shown in FIG. 14, electromagnetic wave detector 100 according to the present embodiment includes two first electrode portions 2a. Electromagnetic wave detector 100 according to the present embodiment is different from electromagnetic wave detector 100 according to Embodiment 1 in that electromagnetic wave detector 100 further includes a pair of first electrode portions 2a. The pair of first electrode portions 2a are disposed at the opposite ends of two-dimensional material layer 1. Electromagnetic wave detector 100 is configured to apply a voltage Vd between the pair of first electrode portions 2a and detect a detection signal Id that is output. In other words, electromagnetic wave detector 100 according to the present embodiment has a transistor-like configuration.

First electrode portion 2a includes a first portion 2a1 and a second portion 2a2. Second portion 2a2 is disposed apart from first portion 2a1. First portion 2a1 is connected to a first end of two-dimensional material layer 1. First portion 2a1 constitutes a source electrode. Second portion 2a2 is connected to a second end of two-dimensional material layer 1. Second portion 2a2 constitutes a drain electrode.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, two-dimensional material layer 1 is disposed between the pair of first electrode portions 2a, as shown in FIG. 14. Electromagnetic wave detector 100 is thus characterized by extraction of an electrical signal from between the pair of first electrode portions 2a. Accordingly, a resistance change of two-dimensional material layer 1 due to the photogating effect generated by the resistance change of heat-absorbing layer HA can be amplified by application of voltage Vd. The amplified charges can be efficiently extracted via first electrode portion 2a. The sensitivity of electromagnetic wave detector 100 is thus improved. Also, the resistance changes caused in heat-absorbing layer HA and semiconductor layer 4 are also output to the detection signal. This improves the sensitivity of electromagnetic wave detector 100.

### Embodiment 6

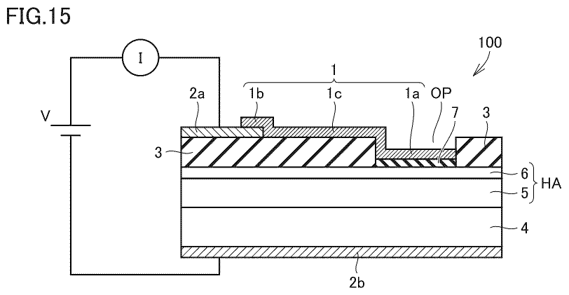

Next, a configuration of electromagnetic wave detector 100 according to Embodiment 6 will be described with reference to FIG. 15. Unless otherwise described, Embodiment 6 has the same components and the same functions and effects as those of Embodiment 1 described above. Thus, the same components as those of Embodiment 1 described above have the same reference characters allotted, and description thereof will not be repeated.

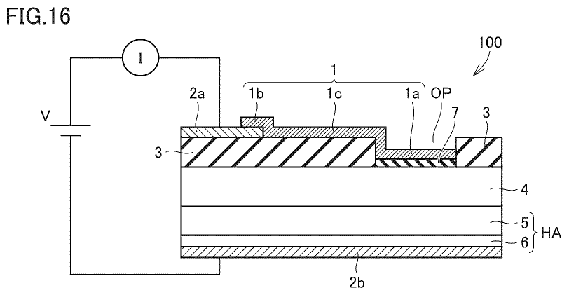

As shown in FIG. 15, electromagnetic wave detector 100 according to the present embodiment further includes a tunnel insulating layer 7. Electromagnetic wave detector 100 according to the present embodiment is different from electromagnetic wave detector 100 according to Embodiment 1 in that electromagnetic wave detector 100 further includes tunnel insulating layer 7. Tunnel insulating layer 7 is wedged between two-dimensional material layer 1 and heat-absorbing layer HA. As shown in FIG. 16, tunnel insulating layer 7 may be wedged between two-dimensional material layer 1 and semiconductor layer 4. Similar effects can be achieved even when tunnel insulating layer 7 is wedged between two-dimensional material layer 1 and semiconductor layer 4. Tunnel insulating layer 7 electrically connects heat-absorbing layer HA to two-dimensional material layer 1. In the present embodiment, thus, two-dimensional material layer 1 is connected to heat-absorbing layer HA with tunnel insulating layer 7 in between. Tunnel insulating layer 7 is disposed in opening OP.

Tunnel insulating layer 7 has such a thickness that allows formation of a tunnel current between two-dimensional material layer 1 and heat-absorbing layer HA when an electromagnetic wave having a detection wavelength enters two-dimensional material layer 1 and heat-absorbing layer HA. Tunnel insulating layer 7 is an insulating layer having a thickness of, for example, 1 nm or more and 10 nm or less. Tunnel insulating layer 7 includes, for example, at least one of a metallic oxide such as alumina (aluminum oxide) or hafnium oxide (HfO₂), an oxide including a semiconductor such as silicon oxide (SiO₂) or silicon nitride (Si₃N₄), and a nitride such as boron nitride (BN).

The method of manufacturing tunnel insulating layer 7 may be determined as appropriate and can be selected from, for example, atomic layer deposition (ALD), vacuum deposition, sputtering, and any other method. Tunnel insulating layer 7 may be formed by oxidation, nitriding, or fluoridation of a surface of heat-absorbing layer HA or semiconductor layer 4. Tunnel insulating layer 7 may be a native oxide formed on the surface of semiconductor layer 4.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment. tunnel insulating layer 7 is wedged between two-dimensional material layer 1 and heat-absorbing layer HA, as shown in FIG. 15. Tunnel insulating layer 7 has such a thickness that allows the formation of a tunnel current between two-dimensional material layer 1 and heat-absorbing layer HA when an electromagnetic wave having a detection wavelength enters two-dimensional material layer 1 and heat-absorbing layer HA. Thus, a tunnel current is generated by the entrance of an electromagnetic wave. This improves the efficiency of injecting a photocurrent into two-dimensional material layer 1 through heat-absorbing layer HA and tunnel insulating layer 7. Consequently, a large photocurrent is injected into two-dimensional material layer 1. This improves the sensitivity of clectromagnetic wave detector 100. Also, a leakage current at the joint interface between two-dimensional material layer 1 and heat-absorbing layer HA can be suppressed by tunnel insulating layer 7. This can reduce a dark current.

### Embodiment 7

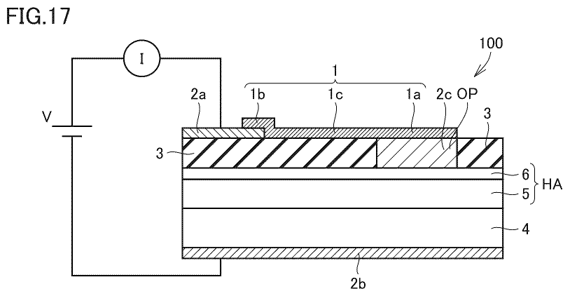

Next, a configuration of electromagnetic wave detector 100 according to Embodiment 7 will be described with reference to FIG. 17. Unless otherwise described, Embodiment 7 has the same components and the same functions and effects as those of Embodiment 1 described above. Thus, the same components as those of Embodiment 1 described above have the same reference characters allotted, and description thereof will not be repeated.

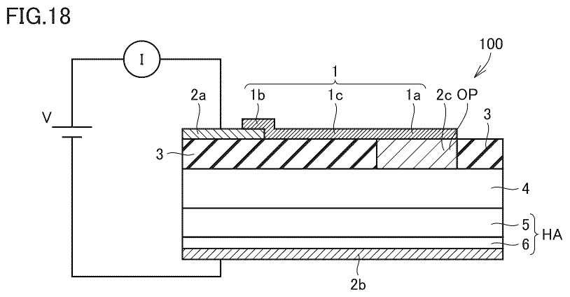

As shown in FIG. 17, electromagnetic wave detector 100 according to the present embodiment further includes a connecting conductor 2c. Electromagnetic wave detector 100 according to the present embodiment is different from electromagnetic wave detector 100 according to Embodiment 1 in that electromagnetic wave detector 100 further includes connecting conductor 2c. Two-dimensional material layer 1 is electrically connected to heat-absorbing layer HA with connecting conductor 2c in between. Connecting conductor 2c is disposed in opening OP. Two-dimensional material layer 1 may be electrically connected to semiconductor layer 4 with connecting conductor 2c in between, as shown in FIG. 18. Similar effects can be achieved even when two-dimensional material layer 1 is electrically connected to semiconductor layer 4 with connecting conductor 2c in between.

Two-dimensional material layer 1 is overlaid on the upper surface of connecting conductor 2c. The lower surface of connecting conductor 2c is electrically connected to heat-absorbing layer HA. Two-dimensional material layer 1 is electrically connected to the upper surface of connecting conductor 2c. The upper surface of connecting conductor 2c is preferably flush with the upper surface of insulating film 3. Two-dimensional material layer 1 preferably extends in a planar manner from the upper surface of insulating film 3 to the upper surface of connecting conductor 2c without bending.

The contact resistance between connecting conductor 2c and two-dimensional material layer 1 is smaller than the contact resistance between two-dimensional material layer 1 and heat-absorbing layer HA. The contact resistance between connecting conductor 2c and heat-absorbing layer HA is smaller than the contact resistance between two-dimensional material layer 1 and heat-absorbing layer HA. The sum of the contact resistance between connecting conductor 2c and two-dimensional material layer 1 and the contact resistance between connecting conductor 2c and heat-absorbing layer HA is smaller than the contact resistance between two-dimensional material layer 1 and heat-absorbing layer HA.

When an electromagnetic wave enters heat-absorbing layer HA through connecting conductor 2c. connecting conductor 2c desirably has a high transmissivity at the wavelength (detection wavelength) of an electromagnetic wave detected by electromagnetic wave detector 100.

Herein, similar effects can be achieved even when the position of heat-absorbing layer HA is changed with the position of semiconductor layer 4, that is, when two-dimensional material layer 1 is joined to semiconductor layer 4 with connecting conductor 2c in between.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, two-dimensional material layer 1 is electrically connected to heat-absorbing layer HA with connecting conductor 2c in between, as shown in FIG. 17. The sum of the contact resistance between connecting conductor 2c and two-dimensional material layer 1 and the contact resistance between connecting conductor 2c and heat-absorbing layer HA is smaller than the contact resistance between two-dimensional material layer 1 and heat-absorbing layer HA. This results in a lower contact resistance than when two-dimensional material layer 1 is directly joined to heat-absorbing layer HA. Thus, attenuation of a detection signal of an electromagnetic wave can be suppressed. This improves the sensitivity of electromagnetic wave detector 100. Also, a dark current can be suppressed because connecting conductor 2c and heat-absorbing layer HA, or connecting conductor 2c and two-dimensional material layer 1 are joined to each other by the Schottky junction.

The upper surface of connecting conductor 2c is preferably flush with the upper surface of insulating film 3. In this case, two-dimensional material layer 1 is formed horizontally without bending, leading to improved carrier mobility of two-dimensional material layer 1. This can improve the detection sensitivity of electromagnetic wave detector 100.

### Embodiment 8

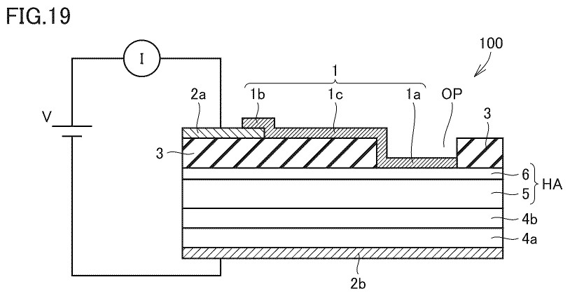

Next, a configuration of electromagnetic wave detector 100 according to Embodiment 8 will be described with reference to FIG. 19. Unless otherwise described, Embodiment 8 has the same components and the same functions and effects as those of Embodiment 1 described above. Thus, the same components as those of Embodiment 1 described above have the same reference characters allotted, and description thereof will not be repeated.

In electromagnetic wave detector 100 according to the present embodiment, semiconductor layer 4 includes a first semiconductor portion 4a and a second semiconductor portion 4b, as shown in FIG. 19. Electromagnetic wave detector 100 according to the present embodiment is different from electromagnetic wave detector 100 according to Embodiment 1 in that semiconductor layer 4 includes first semiconductor portion 4a and second semiconductor portion 4b. Semiconductor layer 4 may further include a third semiconductor portion (not shown). First semiconductor portion 4a is joined to second semiconductor portion 4b. First semiconductor portion 4a is joined to second semiconductor portion 4b by a pn junction. Thus, the pn junction is formed inside semiconductor layer 4. First semiconductor portion 4a is electrically connected to second electrode

portion 2b. Second semiconductor portion 4b is in contact with heat-absorbing layer HA. First semiconductor portion 4a is disposed opposite to two-dimensional material layer 1 relative to second semiconductor portion 4b. Although second semiconductor portion 4b is stacked on first semiconductor portion 4a in FIG. 19, the positional relationship between first semiconductor portion 4a and second semiconductor portion 4b is not limited thereto.

Second semiconductor portion 4b has a conductivity type different from that of first semiconductor portion 4a. First semiconductor portion 4a has a first conductivity type. Second semiconductor portion 4b has a second conductivity type. The first conductivity type is opposite to the second conductivity type. For example, when the conductivity type of first semiconductor portion 4a is the n-type, the conductivity type of second semiconductor portion 4b is the p-type. Thus, semiconductor layer 4 is formed as a diode.

Second semiconductor portion 4b may have an absorption wavelength different from that of first semiconductor portion 4a. Semiconductor layer 4 may be formed as a diode that has sensitivity to a wavelength different from that of heat-absorbing layer HA. First semiconductor portion 4a and second semiconductor portion 4b may be formed as a diode that has sensitivity to a wavelength different from that of heat-absorbing layer HA. First semiconductor portion 4a and second semiconductor portion 4b may be formed between heat-absorbing layer HA and two-dimensional material layer 1 as in Embodiment 2.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, first semiconductor portion 4a is joined to second semiconductor portion 4b, as shown in FIG. 19. Thus, a pn junction is formed inside semiconductor layer 4. Thus, semiconductor layer 4 is formed as a diode. This can suppress a flow of a dark current through semiconductor layer 4.

When first semiconductor portion 4a and second semiconductor portion 4b arc formed as a diode that has sensitivity to a wavelength different from that of heat-absorbing layer HA, wavelengths that can be detected by electromagnetic wave detector 100 are the respective wavelengths detectable by first semiconductor portion 4a, second semiconductor portion 4b, and heat-absorbing layer HA. This enables electromagnetic wave detector 100 to detect wide-band wavelengths.

### Embodiment 9

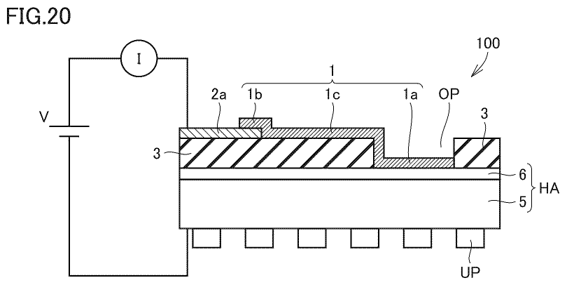

Next, a configuration of electromagnetic wave detector 100 according to Embodiment 9 will be described with reference to FIGS. 20 to 23. Unless otherwise described, Embodiment 9 has the same components and the same functions and effects as those of Embodiment 1 described above. Thus, the same components as those of Embodiment 1 described above have the same reference characters allotted, and description thereof will not be repeated.

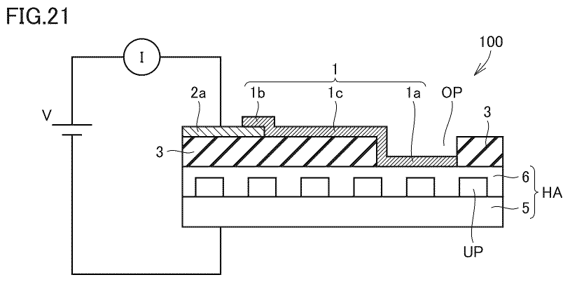

In electromagnetic wave detector 100 according to the present embodiment, a plurality of uneven portions UP are formed on a surface of heat-absorbing layer HA, as shown in FIGS. 20 and 21. Although uneven portions UP are formed on a surface of thermoelectric material layer 5 in FIGS. 20 and 21, uneven portions UP may be formed on a surface of phase-transition material layer 6. Electromagnetic wave detector 100 according to the present embodiment is different from electromagnetic wave detector 100 according to Embodiment 1 in that electromagnetic wave detector 100 further includes uneven portions UP in heat-absorbing layer HA.

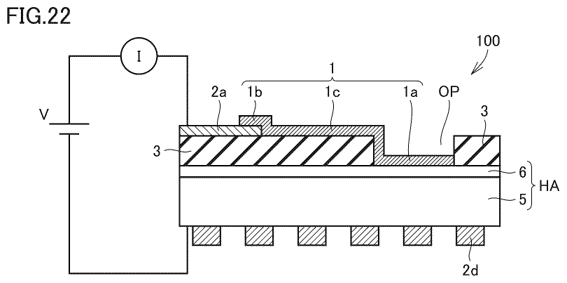

In FIG. 22, a plurality of floating electrodes 2d are formed. Although floating electrodes 2d are formed on thermoelectric material layer 5 in FIG. 22, floating electrodes 2d may be formed on phase-transition material layer 6. Floating electrodes 2d are not connected to a power circuit or the like. In other words, floating electrode 2d is configured as the floating electrode. The material of floating electrode 2d may be determined appropriately as long as it allows electricity to flow therethrough. The material of floating electrode 2d is, for example, a metallic material such as gold (Au), silver (Ag), copper (Cu), aluminum (Al), nickel (Ni), chromium (Cr), or palladium (Pd). The material of floating electrode 2d is preferably a material that generates surface plasmon resonance in floating electrode 2d.

The method of forming uneven portions UP may be determined as appropriate. Uneven portions UP may be formed by, for example, processing heat-absorbing layer HA by dry etching or wet etching.

The method of forming floating electrodes 2d may be determined as appropriate. The method of forming floating electrodes 2d may be the same as, for example, the method of manufacturing first electrode portion 2a described in Embodiment 1.

In the present embodiment, uneven portions UP, floating electrodes 2d are spaced from each other.

In the present embodiment, uneven portions UP and floating electrodes 2d have a one-dimensional or two-dimensional periodic structure. Adjacent uneven portions UP of uneven portions UP, adjacent floating electrodes 2d of floating electrodes 2d are preferably spaced from each other with such a spacing in between that generates surface plasmon resonance in each of uneven portions UP, floating electrodes 2d. A pattern that generates surface plasmon resonance is provided on a surface of heat-absorbing layer HA.

Uneven portions UP, floating electrodes 2d may have the one-dimensional periodic structure. Adjacent uneven portions UP of uneven portions UP, adjacent floating electrodes 2d of floating electrodes 2d are spaced equidistantly in a first direction.

Uneven portions UP and floating electrodes 2d may have the two-dimensional periodic structure. Adjacent uneven portions UP of uneven portions UP, adjacent floating electrodes 2d of floating electrodes 2d are spaced equidistantly in the first direction and a second direction. The second direction intersects the first direction. Uneven portions UP, floating electrodes 2d may be disposed at positions corresponding to grid points of a square grid. Uneven portions UP, floating electrodes 2d may be disposed at, for example, positions corresponding to grid points of a triangle grid. Although not shown, the arrangement of uneven portions UP, floating electrodes 2d is not limited to a cyclically symmetric arrangement. The arrangement of uneven portions UP, floating electrodes 2d may be a non-symmetric arrangement in plan view. The planar shape of uneven portions UP, floating electrodes 2d may be a polygonal shape such as a quadrilateral shape, a circular shape, or a triangular shape, an oval shape, or any other shape.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, uneven portions UP are provided on a surface of heat-absorbing layer HA, as shown in FIGS. 20 and 21. Floating electrodes 2d are disposed to be in contact with heat-absorbing layer HA, as shown in FIG. 22. A pattern that generates surface plasmon resonance is provided on a surface of heat-absorbing layer HA. Uneven portions UP, floating electrodes 2d are spaced from each other. Adjacent uneven portions UP of uneven portions UP, adjacent floating electrodes 2d of floating electrodes 2d are spaced equidistantly in the first direction. The material of uneven portions UP, floating electrodes 2d causes surface plasmon resonance in floating electrode 2d. This allows electromagnetic wave detector 100 to amplify and detect an electromagnetic wave of a wavelength that has such polarization that generates surface plasmon resonance in uneven portions UP, floating electrodes 2d. In other words, absorption by irradiation with an electromagnetic wave increases, resulting in a higher temperature of a surface. This increases the heat absorbed by heat-absorbing layer HA, leading to improved sensitivity of electromagnetic wave detector 100. The temperature difference of thermoelectric material layer 5 can be increased by disposing uneven portions UP, floating electrodes 2d only in the heat generation portion of thermoelectric material layer 5, leading to improved sensitivity of electromagnetic wave detector 100. Polarization dependency is generated in uneven portions UP, floating electrodes 2d according to an electromagnetic wave applied to electromagnetic wave detector 100.

Adjacent uneven portions UP of uneven portions UP, adjacent floating electrodes 2d of floating electrodes 2d are spaced equidistantly in the first direction and the second direction. The material of uneven portions UP, floating electrodes 2d causes surface plasmon resonance in uneven portions UP, floating electrodes 2d. Thus, electromagnetic wave detector 100 can detect only an electromagnetic wave having a wavelength that causes surface plasmon resonance in uneven portions UP, floating electrodes 2d with high sensitivity.

Although not shown, uneven portions UP, floating electrodes 2d may be arranged non-symmetrically in plan view. In this case, electromagnetic wave detector 100 can detect only an electromagnetic wave having such polarization that causes surface plasmon resonance in uneven portions UP, floating electrodes 2d.

Although not shown, two-dimensional material layer 1 may include a plurality of recesses or projections. The plurality of recesses or projections are disposed with such a spacing in between that causes surface plasmon resonance. Since two-dimensional material layer 1 has a high conductivity, surface plasmon resonance occurs in two-dimensional material layer 1. This causes surface plasmon resonance in two-dimensional material layer 1 by the plurality of recesses or projections, similarly to surface plasmon resonance caused by uneven portions UP, floating electrodes 2d. Thus, electromagnetic wave detector 100 can detect only an electromagnetic wave having such polarization or frequency that causes surface plasmon resonance in two-dimensional material layer 1.

Further, uneven portions UP, floating electrodes 2d may radiatively cool the heat generated by irradiation with an electromagnetic wave. At this time, uneven portions UP, floating electrodes 2d are preferably provided on the cooling side of thermoelectric material layer 5. Radiative cooling increases a temperature difference of thermoelectric material layer 5, leading to improved sensitivity of electromagnetic wave detector 100.

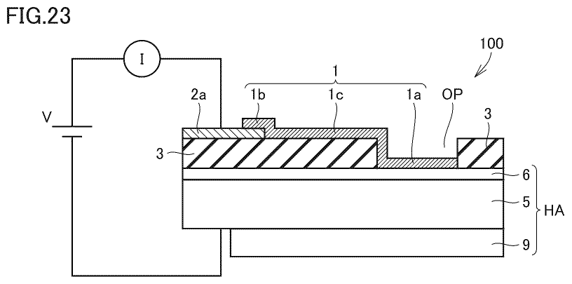

As shown in FIG. 23, a heat-absorbing material or a cooling material 9 may be provided in heat-absorbing layer HA. Heat-absorbing layer HA includes the heat-absorbing material or cooling material 9. The heat-absorbing material or cooling material 9 is provided in a surface of heat-absorbing layer HA. Providing a material increases the amount of heat absorbed from the electromagnetic wave. Providing the heat-absorbing material to the heat generation portion of thermoelectric material layer 5 increases a temperature difference of thermoelectric material layer 5. Providing the cooling material to the cooling portion of thermoelectric material layer 5 increases a temperature difference. This leads to improved sensitivity of electromagnetic wave detector 100.

### Embodiment 10

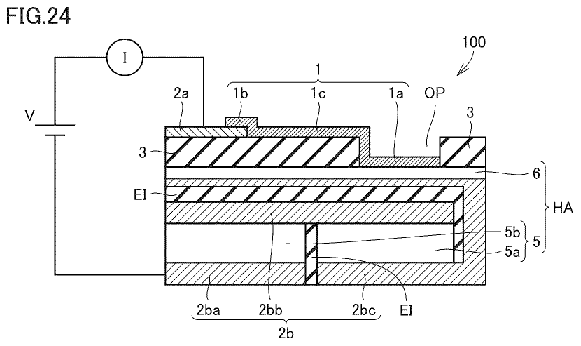

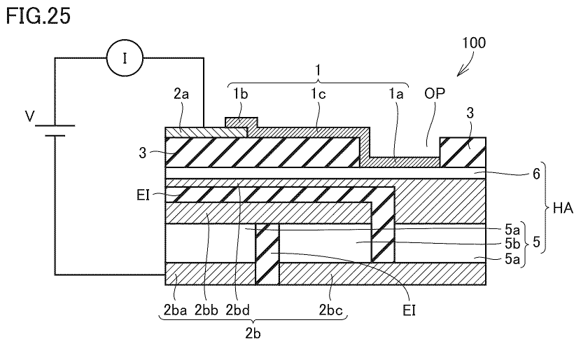

Next, a configuration of electromagnetic wave detector 100 according to Embodiment 10 will be described with reference to FIGS. 24 and 25. Unless otherwise described, Embodiment 10 has the same components and the same functions and effects as those of Embodiment 1 described above. Thus, the same components as those of Embodiment 1 described above have the same reference characters allotted, and description thereof will not be repeated.

As shown in FIG. 24, in electromagnetic wave detector 100 according to the present embodiment, thermoelectric material layer 5 includes a first thermoelectric material layer 5a and a second thermoelectric material layer 5b. Electromagnetic wave detector 100 according to the present embodiment is different from electromagnetic wave detector 100 according to Embodiment 1 in that thermoelectric material layer 5 includes first thermoelectric material layer 5a and second thermoelectric material layer 5b. First thermoelectric material layer 5a and second thermoelectric material layer 5b are disposed in series and are electrically connected to phase-transition material layer 6. First thermoelectric material layer 5a is electrically connected to second thermoelectric material layer 5b.

Second electrode portion 2b includes a first electrode 2ba, a second electrode 2bb, and a third electrode 2be. First electrode 2ba, second thermoelectric material layer 5b, second electrode 2bb, first thermoelectric material layer 5a, third electrode 2be, and phase-transition material layer 6 are connected in series in the stated order. Second electrode 2bb is disposed on the phase-transition material layer 6 side, and first electrode 2ba and third electrode 2be are disposed opposite to phase-transition material layer 6. First thermoelectric material layer 5a and second thermoelectric material layer 5b desirably have different conductivity types. First thermoelectric material layer 5a is preferably joined to second thermoelectric material layer 5b. In other words, first thermoelectric material layer 5a and second thermoelectric material layer 5b preferably form a pn junction. As a result, a temperature difference is caused between a surface of second electrode 2bb and a surface of first electrode 2ba, third electrode 2be, more efficiently providing temperature changes to phase-transition material layer 6. Although an embedded insulating film EI is embedded, embedded insulating film EI may not be used as long as insulation is provided to prevent occurrence of a leakage current from each layer to phase-transition material layer 6. For example, an air gap may be provided.

Next, a configuration of a first modification of electromagnetic wave detector 100 according to Embodiment 10 will be described with reference to FIG. 25.

In electromagnetic wave detector 100 according to the present embodiment, two or more first thermoelectric material layers 5a and two or more second thermoelectric material layers 5b are provided, as shown in FIG. 25. In this case, first thermoelectric material layers 5a and second thermoelectric material layers 5b are preferably connected alternately. Specifically, a pnp junction or an npn junction is preferably provided. Although the number of first thermoelectric material layers 5a and second thermoelectric material layer 5b is three in FIG. 25, more thermoelectric material layers may be provided. The temperature difference between the heat generation portion and the cooling portion increases further with a larger number of thermoelectric material layers. Also in this case, first thermoelectric material layers 5a and second thermoelectric material layers 5b are preferably connected alternately.

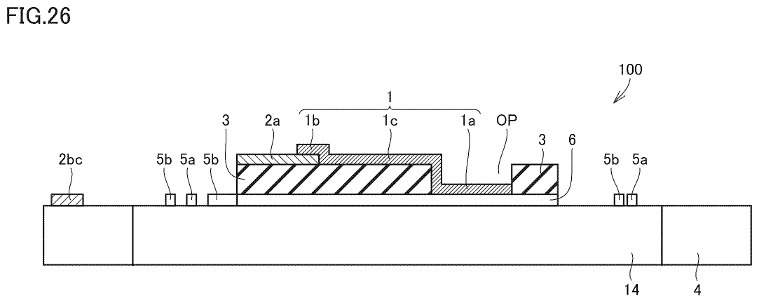

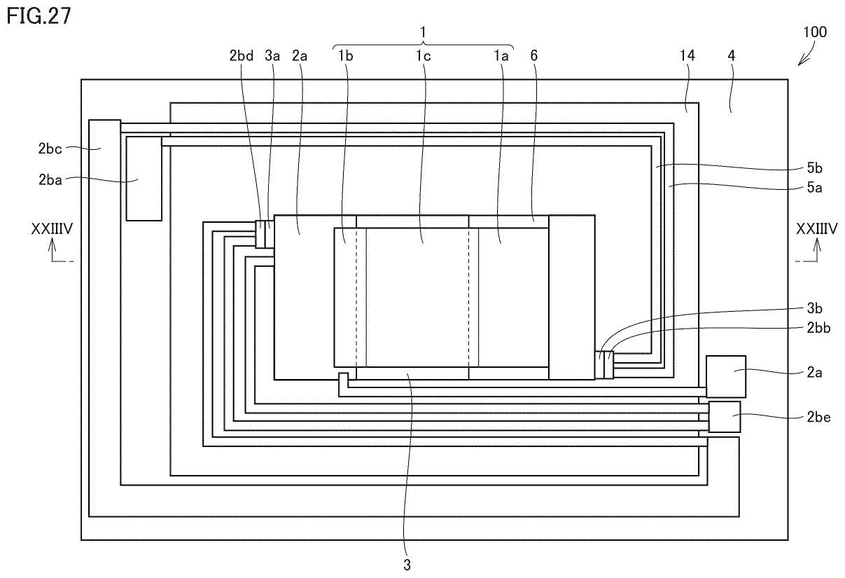

Next, a configuration of a second modification of electromagnetic wave detector 100 according to Embodiment 10 will be described with reference to FIGS. 26 and 27.

In electromagnetic wave detector 100 according to the present embodiment, thermoelectric material layers 5 are provided as pillars having a hollow structure while being connected in series, as shown in FIGS. 26 and 27. Specifically, first thermoelectric material layers 5a and second thermoelectric material layers 5b are alternately connected in series in order of first electrode 2ba, second electrode 2bb, third electrode 2be, fourth electrode 2bd, and fifth electrode 2be. In other words, a temperature difference is increased by thermoelectric material layer 5 provided as a pillar for a long distance by forming the element region at the center portion of the hollow structure as the heat generation portion and the outer circumferential portion of the hollow structure as the cooling portion. In addition, each thermoelectric material layer 5 has a pn junction, leading to a further increase in temperature difference.

The configuration of electromagnetic wave detector 100 according to the present embodiment is also applicable to any other embodiment.

### <Functions and Effects>

Next, the functions and effects of the present embodiment will be described.

Electromagnetic wave detector 100 according to the present embodiment includes thermoelectric material layers 5 of different conductivity types alternately connected in series, as shown in FIGS. 24 to 27. This can increase a temperature difference generated by thermoelectric material layers 5 more than when thermoelectric material layer 5 includes only one thermoelectric material layer. This leads to improved sensitivity of electromagnetic wave detector 100.

When the wavelength of the electromagnetic wave that can be absorbed by first thermoelectric material layer 5a is different from the wavelength of the electromagnetic wave that can be absorbed by second thermoelectric material layer 5b, electromagnetic wave detector 100 can detect a wider-band wavelength than when the wavelengths of the electromagnetic waves that can be absorbed by first thermoelectric material layer 5a and second thermoelectric material layer 5b are the same.

In electromagnetic wave detector 100 according to the second modification of the present embodiment, thermoelectric material layer 5 is provided on hollow 14 as shown in FIGS. 26 and 27. Since each pillar is formed by a pn junction, a temperature difference between the element side (the central portion of hollow 14) and the outer circumferential portion increases to further improve the sensitivity of electromagnetic wave detector 100, in addition to the effects of Embodiment 4. Further, since phase-transition material layer 6 is also provided on hollow 14, heat insulation performance is improved, leading to further improved sensitivity of electromagnetic wave detector 100.

### Embodiment 11

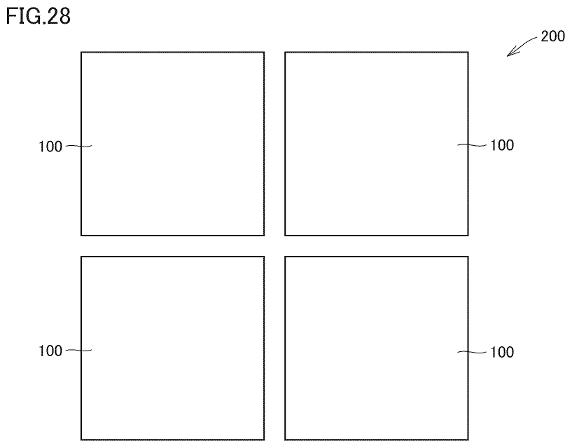

Next, a configuration of an electromagnetic wave detector array 200 according to Embodiment 11 will be described with reference to FIG. 28.

As shown in FIG. 28, electromagnetic wave detector array 200 according to the present embodiment includes a plurality of electromagnetic wave detectors 100 according to any one of Embodiments 1 to 10.

In electromagnetic wave detector array 200 shown in FIG. 28, four electromagnetic wave detectors 100 are disposed in a 2 by 2 array, but the number of electromagnetic wave detectors 100 disposed is not limited thereto. For example, nine electromagnetic wave detectors 100 may be disposed in a 3 by 3 array. Electromagnetic wave detector array 200 shown in FIG. 28 includes electromagnetic wave detectors 100 disposed periodically in two dimensions, but electromagnetic wave detectors 100 may be disposed periodically in one direction. Adjacent electromagnetic wave detectors 100 of electromagnetic wave detectors 100 may be spaced at equal or different spacings.

One second electrode portion 2b (see FIG. 1) may be used as a common electrode in electromagnetic wave detectors 100 as long as the heat-absorbing layers of the respective electromagnetic wave detectors 100 are separated from each other. This results in less wiring of electromagnetic wave detector array 200 than when second electrode portions 2b are independent of each other, leading to a higher resolution of electromagnetic wave detector array 200.

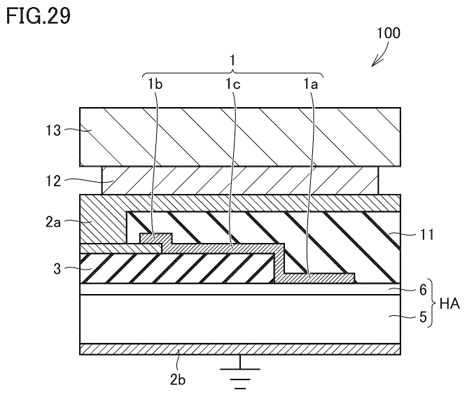

FIG. 29 is a sectional view for describing a structure of connection between one electromagnetic wave detector 100 of electromagnetic wave detector array 200 and a readout circuit 13. As shown in FIG. 29, electromagnetic wave detector 100 may further include an insulating layer 11, which is disposed to cover two-dimensional material layer 1, and a first electrode portion 2a, which is extended onto insulating layer 11. Two-dimensional material layer 1 is electrically connected to first electrode portion 2a. A surface of first electrode portion 2a is electrically connected to readout circuit 13 with a bump 12 in between. In other words, electromagnetic wave detector 100 and readout circuit 13 are connected by a so-called hybrid junction. The structure of connection shown in FIG. 29 is suitable when the material of semiconductor layer 4 (see FIG. 5) is other than Si or when semiconductor layer 4 is not used.

In this case, the material of bump 12 may be any electrically conductive material. The electrically conductive material is indium by way of example but is not limited thereto. The material of first electrode portion 2a is an electrically conductive material such as aluminum silicon, nickel, or gold. Readout circuit 13 is of capacitive transimpedance amplifier (CTIA) type or any other type but is not limited thereto. Other readout methods may be used, such as those used in thermal infrared sensors including quantum infrared detectors and borometers.

Although not shown, electromagnetic wave detectors 100 included in electromagnetic wave detector array 200 may be electromagnetic wave detectors of types different from one another. Electromagnetic wave detectors 100 may be different from one another in detection wavelength. Specifically, electromagnetic wave detectors 100 may be different from one another in detection wavelength selectivity.

When the materials of heat-absorbing layer HA and semiconductor layer 4 of each of electromagnetic wave detectors 100 are different from each other in detection wavelength, for example, a semiconductor material whose detection wavelength is a wavelength of visible light and a semiconductor material whose detection wavelength is a wavelength of infrared light or heat-absorbing layer HA may be used. For example, when electromagnetic wave detector array 200 is applied to an in-vehicle sensor, electromagnetic wave detector array 200 can be used as a camera for visible light images during the day. Further, electromagnetic wave detector array 200 can also be used as an infrared camera during the night. Thus, it is not required to use multiple cameras depending on the detection wavelength of an electromagnetic wave. Next, the functions and effects of the present embodiment will be described.

Electromagnetic wave detector array 200 according to the present embodiment includes electromagnetic wave detectors 100 according to any one of Embodiments 1 to 10 as shown in FIG. 28. Thus, each of electromagnetic wave detectors 100 is used as a detection element, causing electromagnetic wave detector array 200 to function as an image sensor.

In a modification of electromagnetic wave detector array 200 according to the present embodiment, electromagnetic wave detectors have detection wavelengths different from one another. This allows electromagnetic wave detector array 200 to detect electromagnetic waves of at least two different wavelengths.

Thus, electromagnetic wave detector array 200 can discriminate wavelengths of electromagnetic waves in any wavelength range, such as a wavelength range of ultraviolet light, infrared light, terahertz wave, and radio wave, similarly to an image sensor used in the visual light range. As a result, a colorized image can be obtained that shows a difference in wavelength as, for example, a difference in color.

Electromagnetic wave detector array 200 may be used as a sensor other than an image sensor. Electromagnetic wave detector array 200 can be used as a position detection sensor that can detect a position of an object even with a small number of pixels. For example, electromagnetic wave detector array 200 can be used as an image sensor that can detect the intensity of an electromagnetic wave at a plurality of wavelengths. Thus, a colored image can be obtained by detecting a plurality of electromagnetic waves without a color filter that has conventionally been required for a complementary metal-oxide semiconductor (COMS) sensor or the like.

Electromagnetic wave detectors 100 are configured to detect electromagnetic waves having different types of polarization. This causes electromagnetic wave detector array 200 to function as a polarization discrimination image sensor. For example, polarization imaging is enabled by disposing a plurality of electromagnetic wave detectors 100, each of which is composed of four pixels having polarization angles to be detected, that is, 0°, 90°, 45°, and 135°, as one unit. The polarization discrimination image sensor enables, for example, discrimination between an artificial object and a natural object, discrimination between materials, discrimination between a plurality of objects having the same temperature in an infrared wavelength range, discrimination between boundaries of a plurality of objects, and improvement in equivalent resolution.

As described above, electromagnetic wave detector array 200 can detect electromagnetic waves in a wide wavelength range. Electromagnetic wave detector array 200 can also detect electromagnetic waves of different wavelengths.

Electromagnetic wave detector 100 includes readout circuit 13. Thus, a detection signal can be read using readout circuit 13.

### Embodiment 12

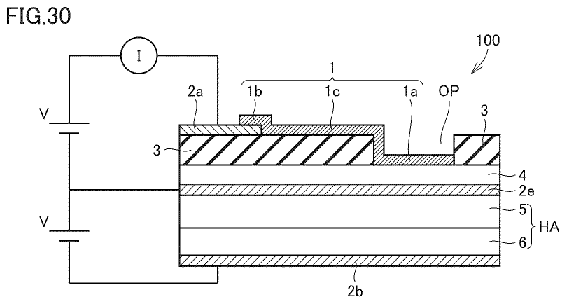

Next, a configuration of electromagnetic wave detector 100 according to Embodiment 12 will be described with reference to FIG. 30. Unless otherwise described, Embodiment 12 has the same components and the same functions and effects as those of Embodiment 2 described above. Thus, the same components as those of Embodiment 2 described above have the same reference characters allotted, and description thereof will not be repeated.

In electromagnetic wave detector 100 according to the present embodiment, a common electrode 2e is disposed between semiconductor layer 4 and heat-absorbing layer HA, as shown in FIG. 30. Electromagnetic wave detector 100 according to the present embodiment is different from electromagnetic wave detector 100 according to Embodiment 2 in that common electrode 2e is disposed between semiconductor layer 4 and heat-absorbing layer HA.

Different voltages are applied between first electrode portion 2a and common electrode 2c and between second electrode portion 2b and common electrode 2c.

Common electrode 2e is preferably a material that has a high thermal conductivity and allows an electromagnetic wave of an absorption wavelength to pass therethrough.

The configuration of electromagnetic wave detector 100 according to the present embodiment is also applicable to any other embodiment.

### <Functions and Effects>

Next, the functions and effects of the present embodiment will be described.

In electromagnetic wave detector 100 according to the present embodiment, common electrode 2e is disposed between heat-absorbing layer HA and semiconductor layer 4. as shown in FIG. 30.

Different voltages are applied between first electrode portion 2a and common electrode 2e and between second electrode portion 2b and common electrode 2e. Thus, a voltage is applied to a graphene-semiconductor Schottky diode between first electrode portion 2a and common electrode 2e, and a voltage is applied to heat-absorbing layer HA between second electrode portion 2b and common electrode 2e.

Application of a voltage to heat-absorbing layer HA can increase a temperature difference caused in thermoelectric material layer 5. Thus, a resistance change due to irradiation with an electromagnetic wave in phase-transition material layer 6 can be controlled appropriately. This can increase the sensitivity of electromagnetic wave detector 100 according to the temperature of the detection wavelength.

As thermoelectric material layer 5 is connected to the graphene-semiconductor Schottky diode with common electrode 2e in between, a temperature difference is caused in the graphene-semiconductor Schottky diode. The graphene-semiconductor Schottky diode changes its electrical characteristics depending on temperature, similarly to a typical diode. A voltage different from that of heat-absorbing layer HA is applied to the graphene-semiconductor Schottky diode, and by controlling this voltage, a current change due to the temperature change can be controlled. Thus, a photocurrent can be extracted by providing a temperature change due to heat-absorbing layer HA to the graphene-semiconductor Schottky diode.

For example, when an electromagnetic wave of a detection wavelength is applied from above electromagnetic wave detector 100, the electromagnetic wave is absorbed in phase-transition material layer 6, causing a temperature change in thermoelectric material layer 5. As this temperature change is provided to the graphene-semiconductor Schottky diode, diode characteristics change, and a resistance between first electrode portion 2a and common electrode 2e changes, enabling detection of the electromagnetic wave.

Also when an electromagnetic wave is applied from below electromagnetic wave detector 100, similar effects can be achieved. In this case, second electrode portion 2b is preferably a material that allows the electromagnetic wave of the detection wavelength to pass therethrough.

### Embodiment 13

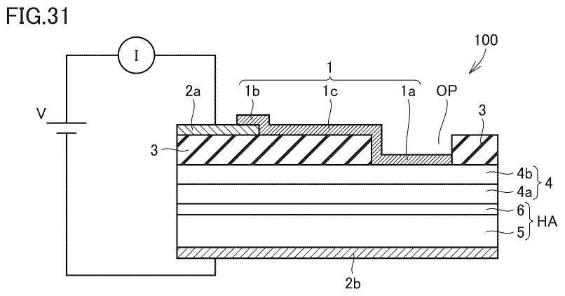

Next, a configuration of electromagnetic wave detector 100 according to Embodiment 13 will be described with reference to FIG. 31. Unless otherwise described, Embodiment 13 has the same components and the same functions and effects as those of Embodiment 1 described above. Thus, the same components as those of Embodiment 1 described above have the same reference characters allotted, and description thereof will not be repeated.

In electromagnetic wave detector 100 according to the present embodiment, semiconductor layer 4 includes first semiconductor portion 4a and second semiconductor portion 4b, as shown in FIG. 31. First semiconductor portion 4a and second semiconductor portion 4b are a photodiode that has sensitivity to the detection wavelength. Electromagnetic wave detector 100 according to the present embodiment is different from electromagnetic wave detector 100 according to Embodiment 1 in that semiconductor layer 4 includes first semiconductor portion 4a and second semiconductor portion 4b and is the photodiode that has sensitivity to the detection wavelength. Semiconductor layer 4 may further include a third semiconductor portion (not shown). First semiconductor portion 4a is joined to second semiconductor portion 4b. First semiconductor portion 4a is joined to second semiconductor portion 4b by a pn junction. Thus, the pn junction is formed inside semiconductor layer 4.

First semiconductor portion 4a is electrically connected to heat-absorbing layer HA. Second semiconductor portion 4b is electrically connected to two-dimensional material layer 1. First semiconductor portion 4a is disposed opposite to two-dimensional material layer 1 relative to second semiconductor portion 4b. Although second semiconductor portion 4b is stacked on first semiconductor portion 4a in FIG. 30, the positional relationship between first semiconductor portion 4a and second semiconductor portion 4b is not limited thereto.

Second semiconductor portion 4b has a conductivity type different from that of first semiconductor portion 4a. First semiconductor portion 4a has a first conductivity type. Second semiconductor portion 4b has a second conductivity type. The first conductivity type is opposite to the second conductivity type. For example, when the conductivity type of first semiconductor portion 4a is the n type, the conductivity type of second semiconductor portion 4b is the p type. Thus, semiconductor layer 4 is configured as a diode.

Semiconductor layer 4 is configured as a photodiode that has sensitivity to the detection wavelength. First semiconductor portion 4a and second semiconductor portion 4b may be formed as a photodiode that has sensitivity to the same wavelength as that of heat-absorbing layer HA.

The configuration of clectromagnetic wave detector 100 according to the present embodiment is also applicable to any other embodiment.

### <Functions and Effects>

Next, the functions and effects of the present embodiment will be described.

In electromagnetic wave detector 100 according to the present embodiment, first semiconductor portion 4a is joined to second semiconductor portion 4b, as shown in FIG. 31. This forms a pn junction inside semiconductor layer 4. Thus, semiconductor layer 4 is configured as a diode. This can suppress a flow of a dark current through semiconductor layer 4.

First semiconductor portion 4a and second semiconductor portion 4b arc configured as the photodiode that has sensitivity to the detection wavelength, and a photocurrent is generated from the photodiode upon irradiation with an electromagnetic wave. As a photocurrent flows through heat-absorbing layer HA, a temperature change occurs in thermoelectric material layer 5, causing a resistance change in phase-transition material layer 6. This can enhance the sensitivity of electromagnetic wave detector 100. Although the electromagnetic wave of the detection wavelength is not necessarily required to be absorbed by heat-absorbing layer HA in the present embodiment, a thermal response and a photon response of the electromagnetic wave can be detected simultaneously when the electromagnetic wave of the detection wavelength is absorbed.

It should be understood that the embodiments disclosed herein are illustrative and non-restrictive in every respect. The scope of the present disclosure is defined by the terms of the claims rather than the description above, and is intended to include any modifications within the scope and meaning equivalent to the terms of the claims.

The following is a summary of various embodiments of the present disclosure as notes.

### Note 1

An electromagnetic wave detector including:
a heat-absorbing layer including a thermoelectric material layer and a phase-transition material layer;
an insulating film disposed on part of the heat-absorbing layer;
a two-dimensional material layer disposed on the heat-absorbing layer and the insulating film and electrically connected to the heat-absorbing layer; and
a first electrode portion disposed on the insulating film and electrically connected to the heat-absorbing layer with the two-dimensional material layer in between.

### Note 2

The electromagnetic wave detector according to note 1, wherein the thermoelectric material layer is disposed to bring a heat generation portion into thermal contact with the phase-transition material layer, the heat generation portion generating heat by a Peltier effect.

### Note 3

The electromagnetic wave detector according to note 2, wherein
the phase-transition material layer is configured such that a resistance value of the phase-transition material layer decreases upon irradiation with an electromagnetic wave, and
the thermoelectric material layer is configured such that a current flows through the thermoelectric material layer upon injection of a charge into the thermoelectric material layer from the phase-transition material layer.

### Note 4

The electromagnetic wave detector according to note 3, further including a semiconductor layer,
wherein the heat-absorbing layer is disposed on the semiconductor layer.

### Note 5

The electromagnetic wave detector according to note 3, further including a semiconductor layer,
wherein the semiconductor layer is disposed between the two-dimensional material layer and the heat-absorbing layer.

### Note 6

The electromagnetic wave detector according to note 4 or 5, further including a second electrode portion,
wherein the second electrode portion is electrically connected to the heat-absorbing layer or the semiconductor layer.

### Note 7

The electromagnetic wave detector according to any one of notes 1 to 6, wherein an air gap is provided below the two-dimensional material layer.

### Note 8

The electromagnetic wave detector according to any one of notes 1 to 6, wherein an air gap is provided below the heat-absorbing layer.

### Note 9

The electromagnetic wave detector according to any one of notes 1 to 6, wherein
the first electrode portion includes a first portion and a second portion disposed apart from the first portion,
the first portion is connected to a first end of the two-dimensional material layer and forms a source electrode, and
the second portion is connected to a second end of the two-dimensional material layer and forms a drain electrode.

### Note 10

The electromagnetic wave detector according to any one of notes 1 to 6, further including a tunnel insulating layer,
wherein the tunnel insulating layer is wedged between the two-dimensional material layer and the heat-absorbing layer.

### Note 11

The electromagnetic wave detector according to any one of notes 1 to 6, further comprising a tunnel insulating layer,
wherein the tunnel insulating layer is wedged between the two-dimensional material layer and the semiconductor layer.

### Note 12

The electromagnetic wave detector according to any one of notes 1 to 6, further including a connecting conductor,
wherein the two-dimensional material layer is electrically connected to the heat-absorbing layer with the connecting conductor in between.

### Note 13

The electromagnetic wave detector according to any one of notes 1 to 6, further including a connecting conductor,
wherein the two-dimensional material layer is electrically connected to the semiconductor layer with the connecting conductor in between.

### Note 14

The electromagnetic wave detector according to any one of notes 4 to 6, wherein
the semiconductor layer includes a first semiconductor portion and a second semiconductor portion having a conductivity type different from that of the first semiconductor portion, and
the first semiconductor portion is joined to the second semiconductor portion.

### Note 15

The electromagnetic wave detector according to any one of notes 1 to 6, wherein a plurality of uneven portions are provided on a surface of the heat-absorbing layer.

### Note 16

The electromagnetic wave detector according to any one of notes 1 to 15, wherein a pattern that generates surface plasmon resonance is provided on a surface of the heat-absorbing layer.

### Note 17

The electromagnetic wave detector according to any one of notes 1 to 6, wherein
the heat-absorbing layer includes a heat-absorbing material or a cooling material, and
the heat-absorbing material or the cooling material is provided on a surface of the heat-absorbing layer.

### Note 18

The electromagnetic wave detector according to any one of notes 1 to 6, wherein
the thermoelectric material layer includes at least one first thermoelectric material layer and at least one second thermoelectric material layer having a conductivity type different from that of the first thermoelectric material layer, and
the at least one first thermoelectric material layer is electrically connected to the at least one second thermoelectric material layer.

### Note 19

The electromagnetic wave detector according to note 18, wherein the at least one first thermoelectric material layer includes two or more first thermoelectric material layers, and the at least one second thermoelectric material layer includes two or more second thermoelectric material layers.

### Note 20

The electromagnetic wave detector according to any one of notes 1 to 19, wherein the thermoelectric material layer includes at least any of a bismuth-telluride-based thermoelectric semiconductor material, a telluride-based thermoelectric semiconductor material, and a silicon-germanium-based thermoelectric semiconductor material.

### Note 21

The electromagnetic wave detector according to any one of notes 1 to 20, wherein the two-dimensional material layer includes a monolayer graphene, a multilayer graphene, a turbostratic stacking graphene, or a plurality of two-dimensional material layers, and has a multilayer structure including two or more selected from these materials.

### Note 22

An electromagnetic wave detector array comprising a plurality of the electromagnetic wave detectors according to any one of notes 1 to 21.

### Note 23

The electromagnetic wave detector array according to note 22, wherein the electromagnetic wave detector includes a readout circuit.

### REFERENCE SIGNS LIST

1 two-dimensional material layer; 2a first electrode portion; 2b second electrode portion; 2c connecting conductor; 2d floating electrode; 2e common electrode; 3 insulating film; 4 semiconductor layer; 4a first semiconductor portion; 4b second semiconductor portion; 5 thermoelectric material layer; 5a first thermoelectric material layer; 5b second thermoelectric material layer; 6 phase-transition material layer; 7 tunnel insulating layer; 9 heat-absorbing material or cooling material; 10 substrate; 11 insulating layer; 12 bump; 13 readout circuit; 14 hollow; 100 electromagnetic wave detector; 200 electromagnetic wave detector array; GP air gap; HA heat-absorbing layer; OP opening; UP uneven portion.

1. An electromagnetic wave detector comprising:
a heat-absorbing layer including a thermoelectric material layer and a phase-transition material layer;
an insulating film disposed on part of the heat-absorbing layer;
a two-dimensional material layer disposed on the heat-absorbing layer and the insulating film and electrically connected to the heat-absorbing layer; and
a first electrode portion disposed on the insulating film and electrically connected to the heat-absorbing layer with the two-dimensional material layer in between, wherein
the thermoelectric material layer is configured such that thermoelectric conversion is generated upon irradiation with an electromagnetic wave,
the phase-transition material layer is configured such that a phase transition is undergone and its resistance is changed upon irradiation with an electromagnetic wave,
the thermoelectric material layer is electrically connected to the phase-transition material layer.

2. The electromagnetic wave detector according to claim 1, wherein the thermoelectric material layer is disposed to bring a heat generation portion into thermal contact with the phase-transition material layer, the heat generation portion generating heat by a Peltier effect.

3. The electromagnetic wave detector according to claim 2, wherein
the phase-transition material layer is configured such that a resistance value of the phase-transition material layer decreases upon irradiation with an electromagnetic wave, and
the thermoelectric material layer is configured such that a current flows through the thermoelectric material layer upon injection of a charge into the thermoelectric material layer from the phase-transition material layer.

4. The electromagnetic wave detector according to claim 3, further comprising a semiconductor layer,
wherein the heat-absorbing layer is disposed on the semiconductor layer.

5. The electromagnetic wave detector according to claim 3, further comprising a semiconductor layer,
wherein the semiconductor layer is disposed between the two-dimensional material layer and the heat-absorbing layer.

6. The electromagnetic wave detector according to claim 4, further comprising a second electrode portion,
wherein the second electrode portion is electrically connected to the heat-absorbing layer or the semiconductor layer.

7. The electromagnetic wave detector according to claim 1, wherein an air gap is provided below the two-dimensional material layer.

8. The electromagnetic wave detector according to claim 1, wherein an air gap is provided below the heat-absorbing layer.

9. The electromagnetic wave detector according to claim 1, wherein
the first electrode portion includes a first portion and a second portion disposed apart from the first portion,
the first portion is connected to a first end of the two-dimensional material layer and forms a source electrode, and
the second portion is connected to a second end of the two-dimensional material layer and forms a drain electrode.

10. The electromagnetic wave detector according to claim 1, further comprising a tunnel insulating layer,
wherein the tunnel insulating layer is wedged between the two-dimensional material layer and the heat-absorbing layer.

11. The electromagnetic wave detector according to claim 5, further comprising a tunnel insulating layer,
wherein the tunnel insulating layer is wedged between the two-dimensional material layer and the semiconductor layer.

12. The electromagnetic wave detector according to claim 1, further comprising a connecting conductor,
wherein the two-dimensional material layer is electrically connected to the heat-absorbing layer with the connecting conductor in between.

13. The electromagnetic wave detector according to claim 5, further comprising a connecting conductor,
wherein the two-dimensional material layer is electrically connected to the semiconductor layer with the connecting conductor in between.

14. The electromagnetic wave detector according to claim 4, wherein
the semiconductor layer includes a first semiconductor portion and a second semiconductor portion having a conductivity type different from that of the first semiconductor portion, and
the first semiconductor portion is joined to the second semiconductor portion.

15. The electromagnetic wave detector according to claim 1, wherein a plurality of uneven portions are provided on a surface of the heat-absorbing layer.

16. The electromagnetic wave detector according to claim 15, wherein a pattern that generates surface plasmon resonance is provided on a surface of the heat-absorbing layer.

17. The electromagnetic wave detector according to claim 1, wherein
the heat-absorbing layer includes a heat-absorbing material or a cooling material, and
the heat-absorbing material or the cooling material is provided on a surface of the heat-absorbing layer.

18. The electromagnetic wave detector according to claim 1, wherein
the thermoelectric material layer includes at least one first thermoelectric material layer and at least one second thermoelectric material layer having a conductivity type different from that of the first thermoelectric material layer, and
the at least one first thermoelectric material layer is electrically connected to the at least one second thermoelectric material layer.

19. The electromagnetic wave detector according to claim 18, wherein the at least one first thermoelectric material layer includes two or more first thermoelectric material layers, and the at least one second thermoelectric material layer includes two or more second thermoelectric material layers.

20. The electromagnetic wave detector according to claim 1, wherein the thermoelectric material layer includes at least any of a bismuth-telluride-based thermoelectric semiconductor material, a telluride-based thermoelectric semiconductor material, and a silicon-germanium-based thermoelectric semiconductor material.

21. The electromagnetic wave detector according to claim 1, wherein the two-dimensional material layer includes a monolayer graphene, a multilayer graphene, a turbostratic stacking graphene, or a plurality of two-dimensional material layers, and has a multilayer structure including two or more selected from these materials.

22. The electromagnetic wave detector according to claim 5, further comprising a common electrode,
wherein the common electrode is disposed between the heat-absorbing layer and the semiconductor layer.

23. The electromagnetic wave detector according to claim 5, wherein
the semiconductor layer includes a first semiconductor portion and a second semiconductor portion having a conductivity type different from that of the first semiconductor portion, and is a photodiode having sensitivity to a detection wavelength, and
the first semiconductor portion is joined to the second semiconductor portion.

24. An electromagnetic wave detector array comprising a plurality of the electromagnetic wave detectors according to claim 1.

25. The electromagnetic wave detector array according to claim 24, wherein the electromagnetic wave detector includes a readout circuit.
